(19) United States
(12) Patent Application Publication
(10) Pub. No.: US 2010/0232861 A1
(43) Pub. Date: Sep. 16, 2010

(54) PROTECTIVE SHEET AND INPUT DEVICE

(75) Inventors: Katsuya SHIBATA, Hyogo (JP); Hideki HARADA, Osaka (JP); Masahiko KITAGAWA, Shiga (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Osaka (JP)

(21) Appl. No.: 12/720,172

(22) Filed: Mar. 9, 2010

(30) Foreign Application Priority Data
Mar. 12, 2009 (JP) 2009-059068
Feb. 4, 2010 (JP) 2010-023260
Feb. 10, 2010 (JP) 2010-027491
Feb. 10, 2010 (JP) 2010-027492

(51) Int. Cl. B41J 5/00; H03K 17/94

(52) U.S. Cl. 400/491; 341/22

(57) ABSTRACT

An input device of the present application includes a plurality of input portions. The input device of the present application has a protective sheet capable of covering at least regions between the input portions. The protective sheet is formed of a plurality of layers including at least a first layer and a second layer. The first layer contains a material having elasticity. The second layer contains a material having a buffering property. With such a configuration, an input device can be realized, which includes a protective sheet that is unlikely to be broken even after the use for a long period of time.

### BACKGROUND OF THE INVENTION

1. Field of the Invention

The present application relates to a protective sheet. The present application relates to an input device having a protective sheet.

2. Description of Related Art

A keyboard mounted on or connected to a personal computer has key-tops for respective characters that can be input. Gaps are provided between adjacent key-tops so that a user can perform a keystroke exactly by a depression operation. In a keyboard having gaps between adjacent key-tops, for example, when a user drops liquid such as coffee the on key-tops by mistake or the user uses the keyboard in the rain or in an environment in which a number of fine particles are flying, the liquid, fine particles, or the like may enter the gaps between the key-tops. If the liquid, fine particles, or the like enter the gaps between the key-tops, movable components placed in a lower portion of the key-top may not be operated smoothly, which results in the user being unable to depress a key-top smoothly in some cases. In order to solve such a problem, various proposals have been made so as to prevent the liquid, fine particles, or the like from entering the gaps between the key-tops in the keyboard.

JP 2000-353443 A discloses a keyboard device in which the surfaces of key-tops in a keyboard are covered with a sheet member having identification information for identifying keys. As the sheet member disclosed by JP 2000-353443 A, a member made of silicone-based rubber and having elasticity is used.

JP 2007-102613 A discloses an input device having a waterproof property while keeping operability and key-touch feeling. Specifically, JP 2007-102613 A discloses a keyboard in which a plurality of rubber domes supporting a plurality of arranged key-tops elastically are provided under the key-tops, and a waterproof sheet in a plane shape as a whole, integrated with the rubber domes, is interposed between the key-tops and a membrane sheet.

However, the sheet member disclosed by JP 2000-353443 A has a single-layered structure of silicone-based rubber, and hence, there is a problem that the sheet member is likely to be broken by being expanded or contracted repeatedly along with the repeated depression operation of the keyboard.

It is difficult to apply the configuration disclosed by JP 2007-102613 A to an input device having a pantograph mechanism with a complicated structure. Further, the configuration disclosed by JP 2007-102613 A has a problem in that a foreign matter is likely to enter a reverse surface of a key-top.

### SUMMARY OF THE INVENTION

An input device disclosed by the present application, includes: a plurality of key-tops; an up-and-down mechanism that supports the key-top so that the key-top rises or falls freely; a contact portion that is switched in synchronization with a rise-and-fall operation of the key-top; and a sheet member placed between the key-top and the contact portion, wherein the sheet member is fixed to a reverse surface of the key-top.

An input device disclosed by the present application having a plurality of input portions includes a protective sheet capable of covering at least regions between the input portions, wherein the protective sheet is formed of a plurality of layers including at least a first layer and a second layer, the first layer contains a material having elasticity; and the second layer contains a material having a buffering property.

A protective sheet disclosed by the present application capable of covering an input portion of an input device is formed of a plurality of layers including at least a first layer and a second layer, wherein the first layer contains a material having elasticity, and the second layer contains a material having a buffering property.

### BRIEF DESCRIPTION OF THE DRAWINGS

FIG. 1 is a perspective view of a notebook personal computer.

FIG. 2 is a cross-sectional view showing an input device in Embodiment 1.

FIG. 3 is a plan view showing the input device in Embodiment 1.

FIG. 4 is a cross-sectional view showing an input device in Embodiment 2.

FIG. 5 is a plan view showing the input device in Embodiment 2.

FIG. 6 is a cross-sectional view showing an input device in Embodiment 3.

FIG. 7 is a cross-sectional view showing an input device in Embodiment 4.

FIG. 8 is a perspective view of a notebook personal computer.

FIG. 9 is a plan view of a keyboard of the notebook personal computer.

FIG. 10A is a cross-sectional view taken along a Z-Z portion in FIG. 9.

FIG. 10B is a cross-sectional view of the keyboard showing a state in which a key is depressed.

FIG. 11A is a plan view of a protective sheet.

FIG. 11B is a cross-sectional view taken along a Z-Z portion in FIG. 11A.

FIG. 12A is a plan view of the keyboard with the protective sheet placed thereon.

FIG. 12B is a cross-sectional view taken along a Z-Z portion in FIG. 12A.

FIG. 13 is a cross-sectional view of a keyboard showing a state in which a key is depressed.

FIG. 14A is a plan view of main portions showing a modified example of the protective sheet.

FIG. 14B is a cross-sectional view taken along a Z-Z portion in FIG. 14A.

FIG. 15 is a plan view of main portions of a keyboard of a notebook personal computer.

FIG. 16A is a cross-sectional view taken along a Z-Z portion in FIG. 15.

FIG. 16B is a cross-sectional view showing a state in which a key is depressed.

FIG. 16C is an enlarged cross-sectional view of a key.

FIG. 17 is a cross-sectional view of a keyboard having a protective sheet according to Example 2.

FIG. 18 is a cross-sectional view of a keyboard having a protective sheet according to Example 3.

FIG. 19 is a cross-sectional view of a keyboard having a protective sheet according to Example 4.

FIG. 20A is a plan view showing a modified example of the protective sheet.

FIG. 20B is a cross-sectional view taken along a Z-Z portion in FIG. 20A.

FIG. 21 is a plan view of main portions of a keyboard of a notebook personal computer.

FIG. 22A is a cross-sectional view taken along a Z-Z portion in FIG. 21.

FIG. 22B is a cross-sectional view showing a state in which a key is depressed.

### DETAILED DESCRIPTION OF THE INVENTION

### Embodiment 1

An input device of the present application is, for example, a keyboard (85 keys) pursuant to the PC Open Architecture Developer's Group (OADG) used in a notebook personal computer, etc. As an example of the input device to which a protective sheet of the present application is applied, a keyboard of a notebook personal computer will be illustrated.

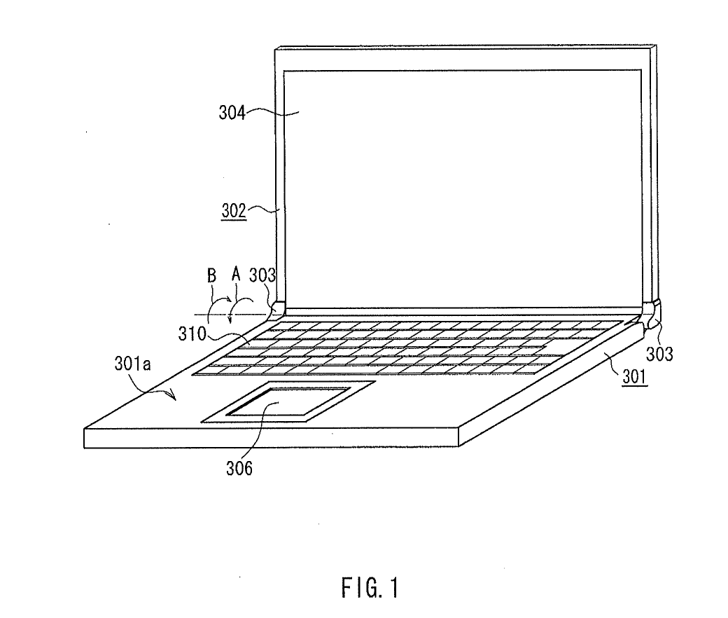

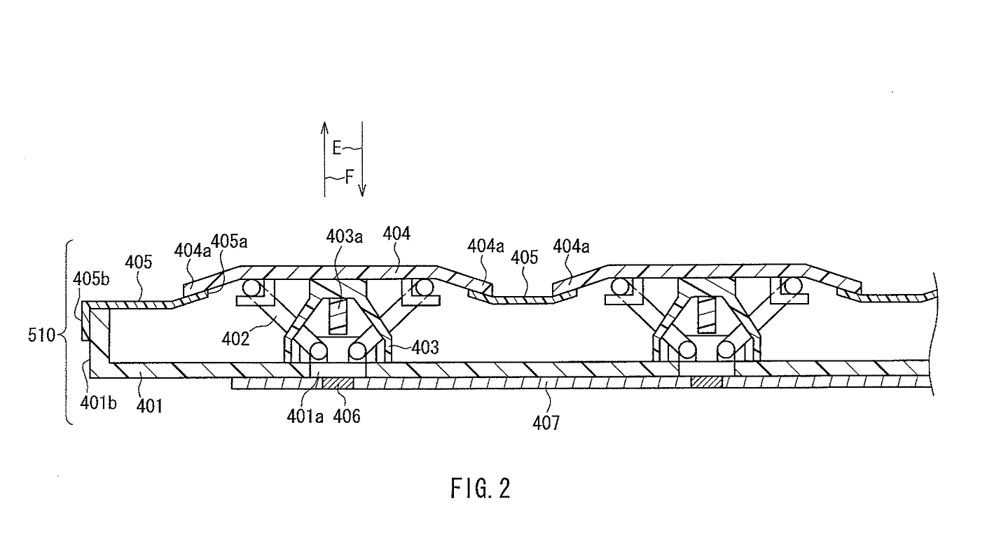

FIG. 1 is a perspective view showing an outer appearance of a notebook personal computer according to the present embodiment. FIG. 2 is a plan view of the vicinity of a keyboard of the notebook personal computer. In the present embodiment, although the keyboard of the notebook personal computer is illustrated as an example of the input device, a keyboard capable of being connected to a desktop personal computer or a keyboard capable of being connected to a personal computer or a personal digital assistance (PDA) may be used. Further, the keyboard in the present embodiment includes, for example, a keyboard capable of inputting only numbers and arithmetic symbols, as well as a keyboard having a QWERTY layout.

As shown in FIG. 1, the notebook personal computer includes a first housing 301 and a second housing 302. The first housing 301 contains a circuit board on which various electric elements are mounted, a hard disk drive, and the like. The second housing 302 has a display panel 304. The first housing 301 and the second housing 302 are supported rotatably with respect to each other by a hinge portion 303. The hinge portion 303 has a rotation shaft supporting the first housing 301 and the second housing 302 rotatably.

A keyboard 310 and a pointing device 306 are placed on an upper surface 301a of the first housing 301. The keyboard 310 receives an input operation of various characters by a user. The pointing device 306 is capable of receiving a contact operation by the user on an operation surface and moving a cursor displayed on the display panel 304 to a desired position.

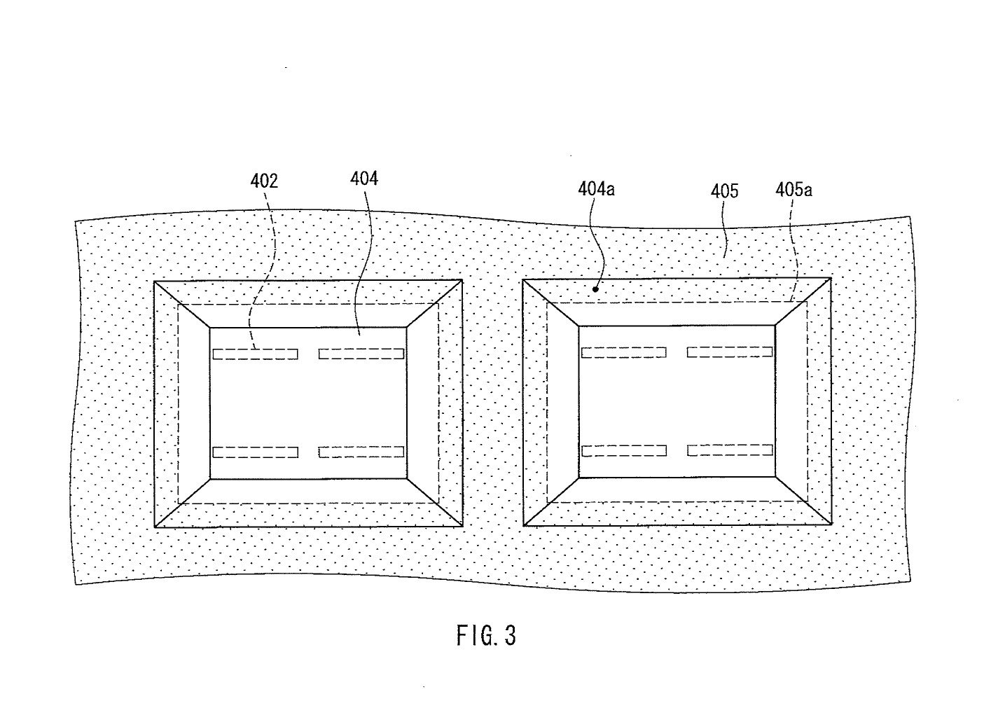

FIG. 2 is a partial cross-sectional view of the input device of the notebook personal computer shown in FIG. 1. FIG. 3 is a partial plan view of the input device according to Embodiment 1.

As shown in FIG. 2, an input device 510 includes pantograph mechanisms 402, rubber springs 403, key-tops 404, a rubber sheet 405, membrane switches 406, and a membrane sheet 407. The pantograph mechanisms 402 support a plurality of arranged key-tops 404. The rubber spring 403 is placed in a lower portion of the key-top 404 and has a protrusion 403a. The membrane sheet 407 includes the membrane switches 406. The membrane switch 406 is a contact portion. The rubber sheet 405 is a sheet member. The rubber sheet 405 has waterproof, dripproof, and dustproof properties. The rubber sheet 405 has openings 405a at positions corresponding to the respective key-tops 404. An end region of the opening 405a of the rubber sheet 405 is connected to be fixed to a fringe portion 404a of a reverse surface of the key-top 404 with an adhesive member. A fringe portion 405b of the rubber sheet 405 is fixed to a fringe portion 401b of an input device frame 401 with an adhesive.

As shown in FIG. 3, the opening 405a has an area smaller than that of the key-top 404. The opening 405a is covered with the key-top 404. The opening 405a is formed in such a manner that the rubber sheet 405 and the pantograph mechanism 402 do not interfere with each other physically.

The operation of the input device 510 will be described.

The key-top 404 supported by the pantograph mechanism 402 is capable of rising or falling between a standby position at which the key-top 404 is pushed up and a depressed position at which the key-top 404 is pushed. The rubber spring 403 has a cup shape that opens toward the input device frame 401. The rubber spring 403 urges the key-top 404 elastically to the standby position at all times. The protrusion 403a positioned at the center of the rubber spring 403 is formed integrally with the rubber spring 403. The protrusion 403a is opposed to the opening 401a formed in the input device frame 401.

The membrane switch 406 detects the depression operation of the key-top 404 electrically to generate an input signal. The membrane switch 406 includes a contact portion having a movable contact point and a fixed contact point (not shown).

When the user depresses the key-top 404 with the finger tip from the standby position shown in FIG. 2 to the depressed position (in a direction indicated by an arrow E), the pantograph 402 rotates about a pivot 402a. At this time, the rubber spring 403 is compressed in the direction indicated by the arrow E, and the protrusion 403a presses the membrane switch 406 through the opening 401a of the input device frame 401.

The operation causes the movable contact point (not shown) of the membrane switch 406 to come into contact with the fixed contact point (not shown) to close the membrane switch 406 electrically. When the membrane switch 406 is closed, the depression operation of the key-top 404 can be detected electrically.

When the user cancels the depressed state of the key-top 404, the key-top 404 is displaced in a direction indicated by an arrow F due to the restoring force of the rubber spring 403 to be pushed up to the standby position. When the rubber spring 403 is restored to the original shape, the protrusion 403a of the rubber spring 403 is detached from the membrane switch 406. Thus, the membrane switch 406 is opened electrically.

While the user is not operating the input device 510 (the key-top 404 is not rising or falling), the gap between the adjacent key-tops 404 and the gap between the key-top 404 and the input device frame 401 are covered with the rubber sheet 405. Further, even when the user is operating the input device 510, the rubber sheet is stretched along with the rise/fall operation of the key-top 404, thereby covering the gap between the adjacent key-tops 404 and the gap between the key-top 404 and the input device frame 501 at all times. Therefore, the rubber sheet 405 can separate the space between the reverse surface of the key-top 404 and the input device frame 401 from an outside space.

In the rubber sheet 405, the opening 405a corresponding to each key-top 404 is formed. The opening 405a prevents the rubber sheet 405 and the pantograph mechanism 402 from interfering with each other. Therefore, dust and moisture from above the input device 510 can be prevented from entering the input device without impairing the operability and key-touch feeling with respect to the key-tops 404. Particularly, the input device 510 in Embodiment 1 can satisfy thinness and waterproof, dripproof, and dustproof properties.

In general, a foreign matter that enters the input device varies depending upon the use environment. For example, in an office, the input device is likely to be exposed to eraser dust, trash such as paper pieces, conductive materials such as a clip (a small nipping metal tool), drops of drink, and the like, in addition to dust. For example, in an outdoor place, the possibility that sand particles, rainwater, etc. may enter the input device is conceivable. The input device 510 in Embodiment 1 can prevent water and a foreign matter from entering the reverse surface of the key-top 404, and hence, the input device 510 can be used without impairing the operability even in a use environment covering a broad range.

### Embodiment 2

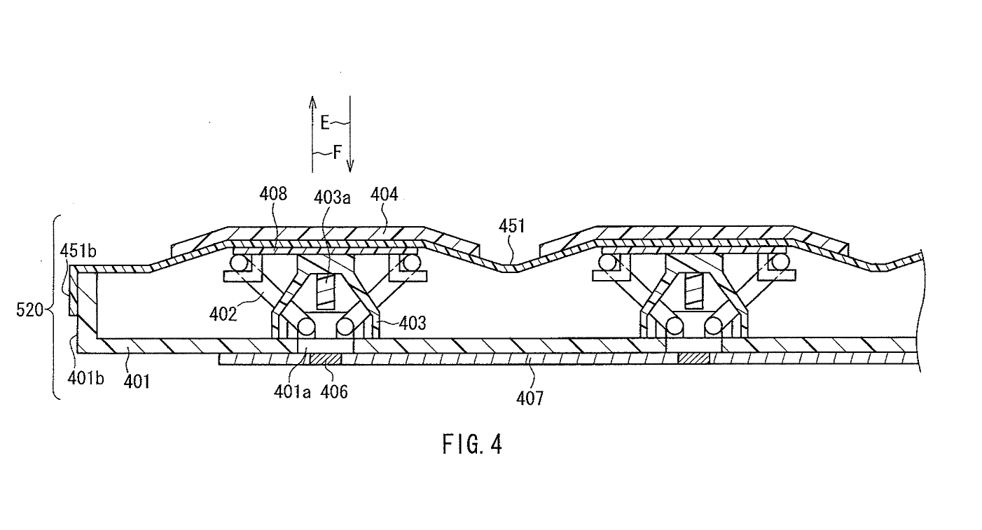

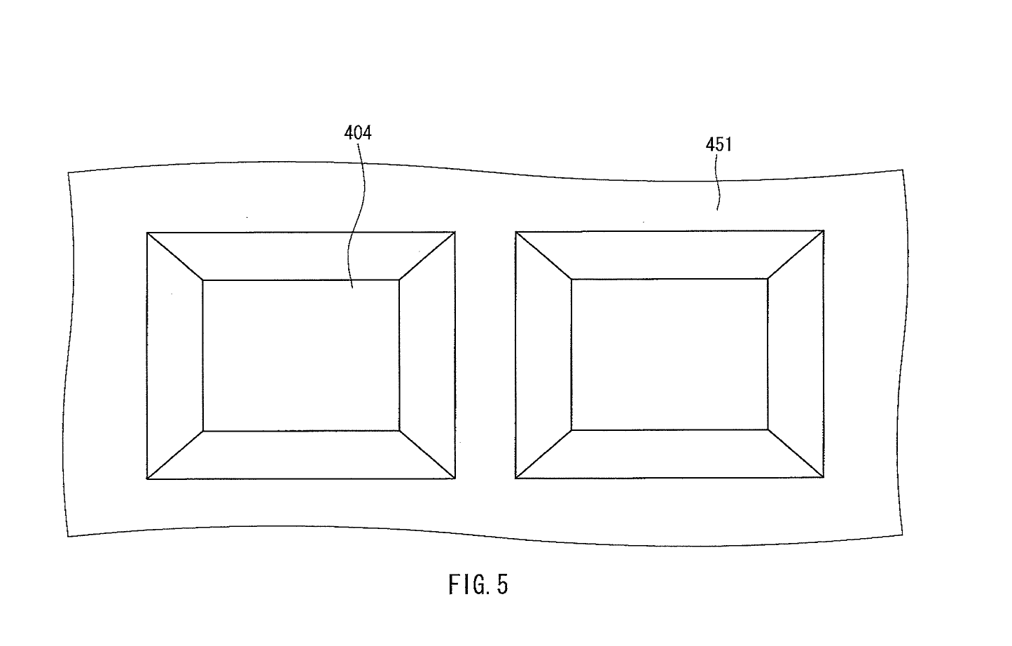

FIG. 4 is a partial cross-sectional view of an input device in Embodiment 2. FIG. 5 is a partial plan view of the input device in Embodiment 2. In FIGS. 4 and 5, the same components as those in FIGS. 2 and 3 are denoted with the same reference numerals as those therein, and the repeated description thereof will be omitted as appropriate.

As shown in FIG. 4, an input device 520 further includes a support plate 408. The support plate 408 is placed on the reverse surface of the key-top 404. The support plate 408 supports the pantograph mechanism 402. In a lower portion of the support plate 408, the rubber spring 403 having the protrusion 403a is placed. In a lower portion of the input device frame 401, the membrane sheet 407 having the membrane switches 406 (contact points) is placed. A rubber sheet 451 (sheet member) has waterproof, dripproof, and dustproof properties. The rubber sheet 451 is interposed between the key-top 404 and the support plate 408, and is fixed to the key-top 404 and the support plate 408 with an adhesive. A fringe portion 451b of the rubber sheet 451 is fixed to the fringe portion 401b of the input device frame 401 with an adhesive.

As shown in FIG. 4, the rubber sheet 451 does not have the opening 405a as shown in FIG. 2 in a lower portion of the key-top 404. The rubber sheet 451 is placed so as to cover integrally an entire region (not shown) in which the key-tops 404 of the input device 520 are arranged.

In the input device 520, the rubber sheet 451 and the support plate 408 are interposed between the key-top 404 and the rubber spring 403. The operation thereof is the same as that of Embodiment 1, so that the description thereof will be omitted.

In the input device 520 according to Embodiment 2, the rubber sheet 451 can be placed without considering the physical interference between the pantograph mechanism 402 and the rubber sheet 451, while keeping the same waterproof, dripproof, and dustproof effects as those in Embodiment 1. Thus, the rubber sheet 451 can be positioned easily, and the process of producing the input device 520 is simplified.

### Embodiment 3

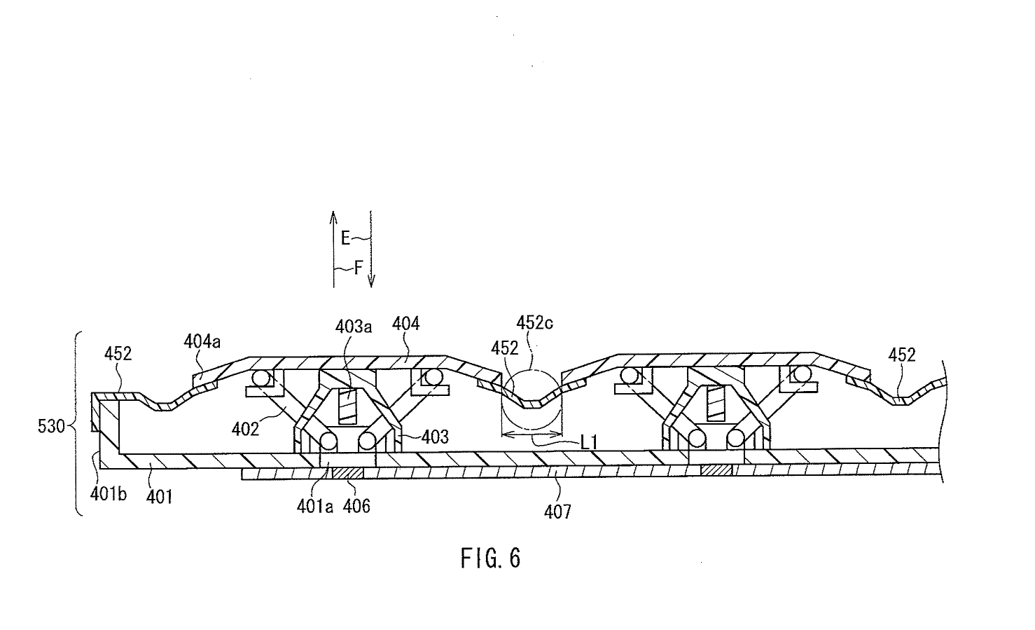

FIG. 6 is a partial cross-sectional view of an input device in Embodiment 3. In FIG. 6, the same components as those in FIG. 2 are denoted with the same reference numerals as those therein, and the repeated description will be omitted as appropriate.

As shown in FIG. 6, an input device 530 is different from Embodiment 1 in the configuration of the sheet member. More specifically, a rubber sheet 452 (sheet member) shown in FIG. 6 has waterproof, dripproof, and dustproof properties. The rubber sheet 452 is fixed to the fringe portion 404a of the reverse surface of the key-top 404 and the fringe portion 401b of the input device frame 401 with an adhesive. The rubber sheet 452 is fixed with a loose portion 452c so that a portion positioned around each key-top 404 is longer than a distance L1 between the adjacent key-tops 404. Herein, the loose portion 452c of the rubber sheet 452 can be realized by molding the rubber sheet 452, or the like.

The rubber sheet 452 has the openings 405a corresponding to the respective key-tops 404. The rubber sheet 452 is fixed to the reverse surface of the key-top 404 and the input device frame 401 so as not to interfere with the pantograph mechanism 402.

The operation of the input device 530 is the same as that of Embodiment 1, and hence, the detailed description thereof will be omitted.

The input device 530 in Embodiment 3 has the same waterproof, dripproof, and dustproof effects as those in Embodiment 1. Further, the rubber sheet 452 has the loose portion 452c in a portion positioned around the key-top 404. This alleviates the tension on the rubber sheet 452 when the key-top rises or falls and prolongs the life of the rubber sheet 452, thereby enhancing the durability of the input device 530.

### Embodiment 4

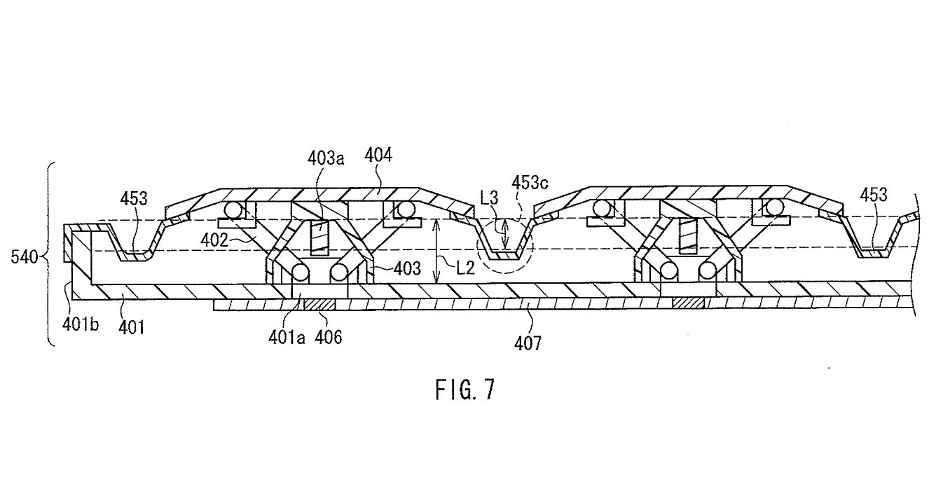

FIG. 7 is a partial cross-sectional view of an input device in Embodiment 4. In FIG. 7, the same components as those in FIG. 6 are denoted with the same reference numerals as those therein, and the repeated description thereof will be omitted as appropriate.

As shown in FIG. 7, an input device 540 is different from Embodiment 3 in the configuration of the sheet member. More specifically, a rubber sheet 453 (sheet member) has waterproof, dripproof, and dustproof properties. The rubber sheet 453 is fixed to the fringe portion 404a of the reverse surface of the key-top 404 and the fringe portion 401b of the input device frame 401 with an adhesive. The rubber sheet 453 has a loose portion 453c around the key-top 404. The loose portion 453c sets a distance L3 from a portion connected to the key-top 404 to a bent portion to be at least ½ of a stroke L2 of the key-top 404 in the rise/fall direction. Herein, the input device 540 can be produced easily by molding the loose portion 453c previously in the rubber sheet 453.

The method for fixing the rubber sheet 453 to the key-top 404 and the operation of the input device 540 are the same as those in Embodiment 1 or 3, so that the detailed description thereof will be omitted.

In the input device 540 in Embodiment 4, a size L3 of the loose portion 453c of the rubber sheet 453 (the size L3 refers to a distance from the portion connected to the key-top 404 to the bent portion) is set to be at least ½ of the stroke L2 of the key-top 404 in the rise/fall direction. Thus, the rubber sheet 453 is unlikely to receive tension when the key-top 404 rises or falls. Thus, the life of the rubber sheet 453 can be enhanced further, and the durability of the input device 540 can be enhanced.

The rubber sheet in the above embodiment is an example of the sheet member. The sheet member may be any elastic member that has at least waterproof, dripproof, and dustproof properties and that is capable of being stretched along with the rise/fall operation of the key-top 204. As the sheet member, a sheet material based on resin such as silicone, polyurethane, vinyl chloride, polyolefin, or the like can be used. Further, in the configurations of Embodiments 3 and 4, even a sheet member with a smaller elasticity can be used.

Further, as the method for fixing the rubber sheet 453 to the key-top 404, integral molding, thermocompression bonding, or the like also can be used in addition to the adhesion using an adhesive. As the method for fixing the rubber sheet 453 to the support plate 408, integral molding, thermocompression bonding, or the like also can be used in addition to the adhesion using an adhesive. As the method for fixing the rubber sheet 453 to the input device frame 401, integral molding, thermocompression bonding, or the like also can be used in addition to the adhesion using an adhesive.

Regarding Embodiments 1 to 4, the following notes are disclosed.

(Note 1)

An input device includes an input device frame, a plurality of key-tops arranged on the input device frame, a pantograph mechanism that is placed between the key-top and the input device frame and supports the key-top with respect to the input device frame so that the key-top rises or falls freely, a contact portion that is switched in synchronization with the rise/fall of the key-top, and a sheet member. The sheet member is interposed between the key-top and the contact portion and is fixed to the reverse surface of the key-top.

According to the above configuration, when the input device is being operated, the finger of a user contacts the key-top directly, and hence, the operability and key-touch feeling of the input device will not be impaired. Further, the sheet member fixed to the reverse surface of the key-top can prevent water or a foreign matter from entering the reverse surface of the key-top and the contact portion through the gap between the arranged key-tops.

(Note 2)

An input device includes an input device frame, a plurality of key-tops arranged on the input device frame, a support plate placed on a reverse surface of the key-top, a pantograph mechanism that is placed between the support plate and the input device frame and supports the support plate with respect to the input device frame so that the support plate rises or falls, a contact portion that is switched in synchronization with the rise/fall of the key-top together with the support plate, and a sheet member. The sheet member is interposed between the key-top and the support plate to be fixed.

According to the above configuration, when the input device is being operated, the finger of a user contacts the key-top directly, and hence, the operability and key-touch feeling of the input device will not be impaired. Further, the sheet member fixed to the reverse surface of the key-top can prevent water or a foreign matter from entering the reverse surface of the key-top and the contact portion through the gap between the arranged key-tops. Further, the sheet member can be placed without considering the physical interference between the pantograph mechanism and the sheet member, and hence, the sheet member can be positioned easily and the process of producing the input device can be simplified.

(Note 3)

In the input device, it is desired that a fringe portion of the sheet member is fixed to a fringe portion of the input device frame. According to such a configuration, the sheet member can be placed so as to cover the entire surface of the input device frame of the input device, whereby the waterproof and dustproof properties of the entire input device can be realized.

(Note 4)

In the input device, it is desired that the sheet member between the adjacent key-tops is fixed with looseness so that the sheet member is longer than the distance between the adjacent key-tops. According to such a configuration, the tension applied to the sheet member during the rise/fall of the key-top involved in the operation of the input device is alleviated, and hence, the durability of the input device is enhanced.

(Note 5)

In the input device, it is desired that the looseness of the sheet member is at least ½ of the rise/fall stroke of the key-top. According to such a configuration, the sheet member is unlikely to receive tension during the rise/fall of the key-top involved in the operation of the input device, and hence, the durability of the input device is enhanced further.

### Embodiment 5

### 1. Configuration of an Input Device

Hereinafter, a keyboard of a notebook personal computer will be illustrated as an example of an input device to which a protective sheet of the present application is applied.

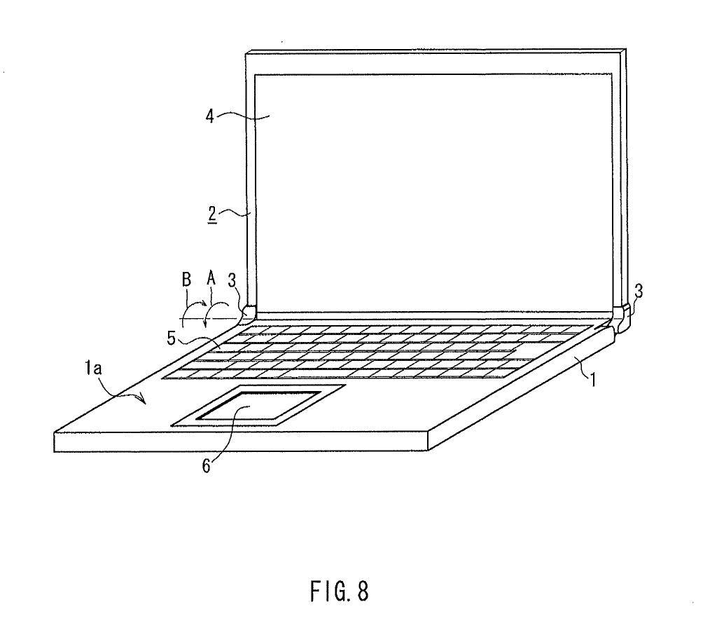

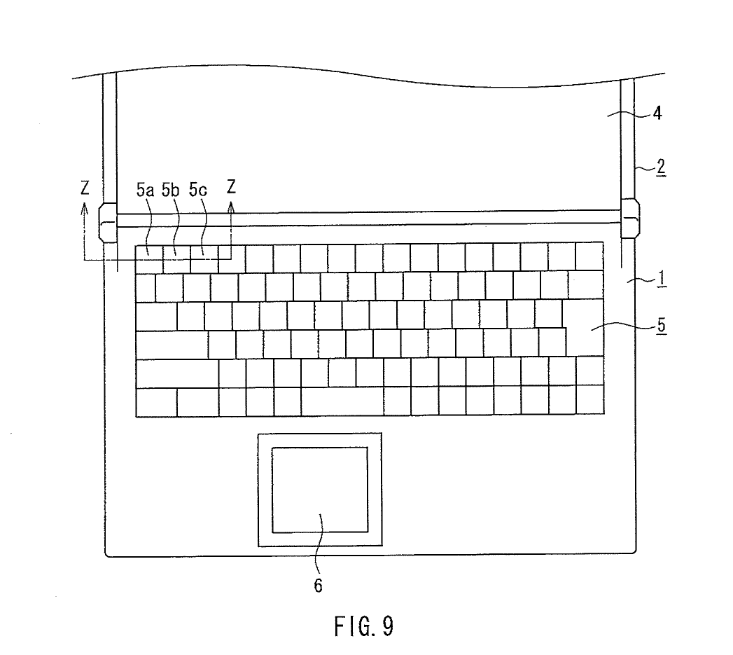

FIG. 8 is a perspective view showing an outer appearance of a notebook personal computer according to the present embodiment. FIG. 9 is a plan view of the vicinity of a keyboard of the notebook personal computer. In the present embodiment, although the keyboard of the notebook personal computer is illustrated as an example of the input device, a keyboard mounted on a desktop personal computer, a keyboard capable of being connected externally to a personal computer or a personal digital assistance (PDA) may be used. Further, the keyboard in the present embodiment includes, for example, a keyboard capable of inputting only numbers and arithmetic symbols, as well as a keyboard having a QWERTY layout.

As shown in FIG. 8, the notebook personal computer includes a first housing 1 and a second housing 2. The first housing 1 contains a circuit board on which various electric elements are mounted, a hard disk drive, and the like. The second housing 2 has a display panel 4. The first housing 1 and the second housing 2 are supported rotatably with respect to each other by a hinge portion 3. The hinge portion 3 has a rotation shaft supporting the first housing 1 and the second housing 2 rotatably.

A keyboard 5 and a pointing device 6 are placed on an upper surface la of the first housing 1. The keyboard 5 receives an input operation of various characters by a user. The pointing device 6 is capable of receiving a contact operation by the user on an operation surface and moving a cursor displayed on the display panel 4 to a desired position.

As shown in FIG. 9, the keyboard 5 has a plurality of keys. Each key is assigned characters and functions that can be input. Although the key layout of the keyboard 5 is set to be a QWERTY layout in the present embodiment, the key layout is not limited thereto and may be another key layout such as an AZERTY layout or a Dvorak layout. Although not shown, character names, function names, and the like that can be input by depressing the key-top are printed on a top surface (the face that is depressed with the finger when the user inputs a character with the keyboard 5) of each key-top in the keyboard 5.

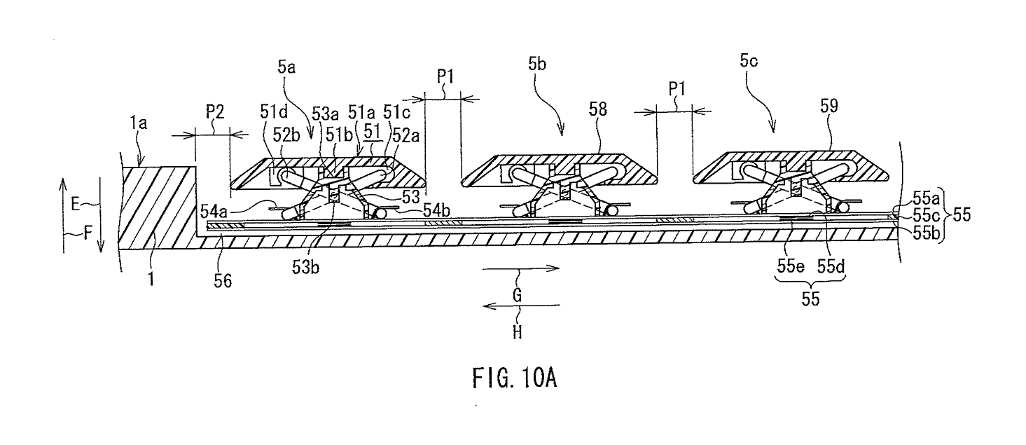

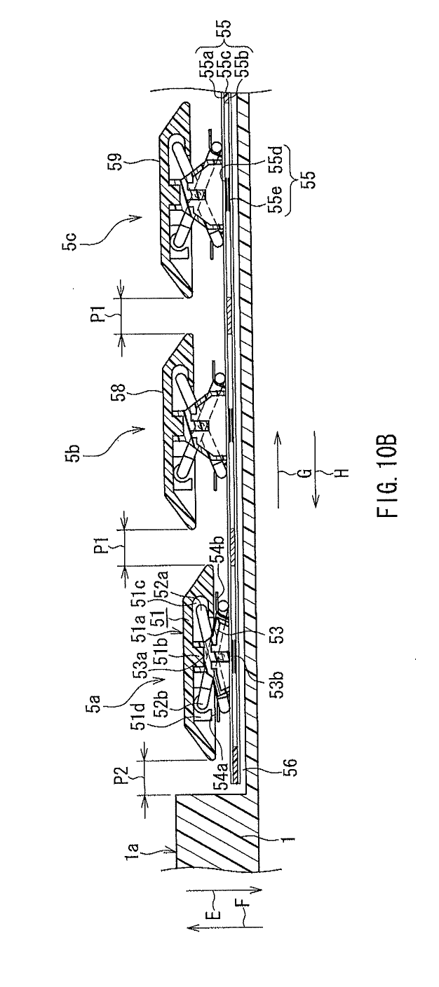

FIGS. 10A and 10B are cross-sectional views taken along a Z-Z portion in FIG. 9. FIG. 10A shows a state in which a key is not depressed. FIG. 10B shows a state in which one of the keys is depressed. Hereinafter, the specific configuration of the keyboard 5 will be described by illustrating a key 5a as an example.

The key 5a includes a key-top 51, link members 52a and 52b, and a dome portion 53. The key-top 51 is formed so as to have a cross-section substantially in a trapezoid as shown in the figure. On a top surface 51a of the key-top 51, characters, symbols, and the like representing the functions of each key are printed. On a lower surface side (reverse side of the top surface 51a) of the key-top 51, a protrusion 51b is formed substantially at the center, and on both sides of the protrusion 51b, link support portions 51c and 51d are formed. The protrusion 51b is fitted in a concave portion 53a formed in the dome portion 53. The link support portion 51c has an opening, and one end of the link member 52a is fitted in the opening with looseness. The link support portion 51d has an opening, and one end of the link member 52b is fitted in the opening with looseness.

The link members 52a and 52b are placed so as to cross each other. The link member 52a has one end supported rotatably by the link support portion 51c and the other end supported movably by the link support portion 54a formed on a membrane portion 55. The link member 52b has one end supported rotatably by the link support portion 51d and the other end supported movably by the link support portion 54b formed on the membrane portion 55. The link members 52a and 52b are those which guide the key-top 51 in a downward direction indicated by an arrow E and an upward direction indicated by an arrow F.

The dome portion 53 is formed in a dome shape in which the inside has a hollow structure as shown in FIG. 10A. In the dome portion 53, the protrusion 51b is fitted in the concave portion 53a formed at an upper end, and the lower end of the dome portion 53 is fixed to the membrane portion 55. The dome portion 53 is formed of an elastic material such as rubber, which is deformed when an external pressure is applied and keeps the shape shown in FIG. 10A while a pressure is not applied. A protrusion 53b is formed on a reverse side of the concave portion 53a of the dome portion 53. The dome portion 53 is a member that supports the key-top 51 so that the key-top 51 is not displaced in the direction indicated by the arrow E due to the self weight when the key-top 51 is not depressed as shown in FIG. 10A. The dome portion 53 is compressed and deformed along with the displacement of the key-top 51 in the direction indicated by the arrow E, when the user depresses the key top 51 in the direction indicated by the arrow E from the state where the key-top 51 is not depressed as shown in FIG. 10A.

The link support portion 54a supports the other end of the link member 52a. The link support portion 54b supports the other end of the link member 52b. When the key-top 51 is displaced in the direction indicated by the arrow E from the position shown in FIG. 10A, the other end of the link member 52a moves in a direction indicated by an arrow H through an opposed region of the link support portion 54a and the membrane member 55, and the other end of the link member 52b moves in a direction indicated by an arrow G through the opposed region between the link support portion 54b and the membrane member 55. Further, when the key-top 51 is placed at the position shown in FIG. 10A, the other end of the link member 52a comes into contact with an inner wall at a right end in the drawing surface of the link support portion 54a, and the other end of the link member 52b comes into contact with an inner wall at a left end on the drawing surface of the link support portion 54b. This can restrict the movement of the other end of the link member 52a in the direction indicated by the arrow G, and restrict the movement of the other end of the link member 52b in the direction indicated by the arrow H. Thus, the displacement of the key-top 51 in the direction indicated by the arrow F from the position shown in FIG. 10A can be restricted.

The membrane portion 55 has an upper membrane sheet 55a, a lower membrane sheet 55b, a spacer 55c, an upper contact point 55d, and a lower contact point 55e. The upper membrane sheet 55a and the lower membrane sheet 55b are placed substantially in parallel to each other. The upper membrane sheet 55a and the lower membrane sheet 55b respectively have a base. The base can be formed, for example, of silicone rubber. In the base, a wiring pattern (not shown) and the contact points 55d and 55e are formed. The wiring pattern, and the contact points 55d and 55e can be formed of, for example, Ag ink. The upper contact point 55d is formed on a surface of the upper membrane sheet 55a opposed to the lower membrane sheet 55b. The lower contact point 55e is formed on a surface of the lower membrane sheet 55b opposed to the upper membrane sheet 55a. The upper contact point 55d and the lower contact point 55e are connected electrically to a wiring pattern (not shown) connected to an electric circuit board (not shown) in the first housing 1. The upper membrane sheet 55a and the lower membrane sheet 55b are attached to each other with the spacer 55c interposed therebetween. The spacer 55c has an opening at least in the upper contact point 55d, the lower contact point 55e, and the periphery thereof so that the upper membrane sheet 55a and the lower membrane sheet 55b are communicated with each other spatially, thereby preventing interference with the electric contact between the upper contact point 55d and the lower contact point 55e involved in the elastic deformation of the upper membrane sheet 55a. A gap can be formed between the upper membrane sheet 55a and the lower membrane sheet 55b by interposing the spacer 55c between the upper membrane sheet 55a and the lower membrane sheet 55b. The spacer 55c can form a gap at least between the upper contact point 55d and the lower contact point 55e. When a gap is formed between the upper contact point 55d and the lower contact point 55e, the contact between the upper contact point 55d and the lower contact point 55e can be prevented while the key-top 51 is not depressed.

A gap P1 is present respectively between the key-top 51 of the key 5a and a key-top 58 of a key 5b, and between the key-top 58 of the key 5b and a key-top 59 of a key 5c. As though not shown, there is a gap between adjacent key-tops mounted on the keyboard 5. Further, even in a portion where the key-top and a part of the first housing 1 are adjacent to each other, a gap (for example, a gap P2 shown in FIG. 10A) is present between the key-top and the first housing.

Hereinafter, the operation of the keyboard 5 will be described.

FIG. 10A shows a state in which the key-top 51 is not depressed. In the state shown in FIG. 10A, the position (raised position) not shown is kept by the dome portion 53, and the displacement in the direction indicated by the arrow E due to the self-weight is restricted. At this time, the contact points 55d and 55e are separated from each other.

When the user depresses the key-top 51 with the finger or the like in the direction indicated by the arrow E from the above state, the key-top 51 is displaced in the direction indicated by the arrow E while being guided with the link members 52a and 52b. At this time, the dome portion 53 is compressed and deformed with a pressure force in the direction indicated by the arrow E applied to the key-top 51. Further, the key-top 51 is supported by the link members 52a and 52b, and hence, the key-top 51 is displaced in the direction indicated by the arrow E while keeping the state parallel to the membrane portion 55. When the key-top 51 is displaced in the direction indicated by the arrow E, the other end of the link member 52a moves in the direction indicated by the arrow H while being supported by the link support portion 54a, and the other end of the link member 52b moves in the direction indicated by the arrow G while being supported by the link support portion 54b.

As shown in FIG. 10B, when the user depresses the key-top 51 to a predetermined position, the protrusion 53b formed at the dome portion 53 comes into contact with the upper membrane sheet 55a. When the user further depresses the key-top 51 from this state, the protrusion 53b pressures the upper membrane sheet 55a, and the upper membrane sheet 55a is curved and deformed in the direction indicated by the arrow E. When the upper membrane sheet 55a is deformed to a predetermined position, the upper contact point 55d and the lower contact point 55e come into contact with each other. Due to the contact between the upper contact point 55d and the lower contact point 55e, the wiring pattern formed in the upper membrane sheet 55a and the wiring pattern formed in the lower membrane sheet 55b are brought into a conducting state, whereby an electrical ON state can be obtained. Since the wiring pattern is connected electrically (not shown since the connection state is well-known) to the signal processing circuit placed in the first housing 1, signal processing corresponding to the depressed key is performed in the signal processing circuit. For example, in the case where the depressed key is assigned a predetermined character input function, the display portion 4 placed in the second housing 2 is controlled to display the assigned character.

When the user retracts the finger from the key-top 51 in the state shown in FIG. 10B, the key-top 51 rises in the direction indicated by the arrow F due to the resilient restoring force of the dome portion 53. More specifically, the dome portion 53 has a resilient restoring force to such a degree as to push up the key-top 51 in the direction indicated by the arrow F. At this time, since the key-top 51 is guided by the link members 52a and 52b, the key-top 51 rises in the direction indicated by the arrow F while keeping the state parallel to the membrane portion 55. As shown in FIG. 10A, the dome portion 53 is restored from the compressed and deformed state to the original shape, whereby the protrusion 53b pressing the upper membrane sheet 55a leaves from the upper membrane sheet 55a. When the protrusion 53b leaves from the upper membrane sheet 55a, the upper membrane sheet 55a is restored from the curved and deformed state to the original shape (shape opposed in parallel to the lower membrane sheet 55b as shown in FIG. 10A), and the upper contact point 55d and the lower contact point 55e are separated from each other. When the upper contact point 55d and the lower contact point 55e are separated from each other, the wiring pattern of the upper membrane sheet 55a and the wiring pattern of the lower membrane sheet 55b are separated electrically from each other, whereby an electrical OFF state is obtained.

As shown in FIG. 10A, when the key-top 51 rises to a predetermined position, the other end of the link member 52a comes into contact with the inner wall at the right end on the drawing surface of the link support portion 54a, and the other end of the link member 52b comes into contact with the inner wall at the left end on the drawing surface of the link support portion 54b. This restricts the movement of the other end of the link member 52a in the direction indicated by the arrow G, and the movement of the other end of the link member 52b in the direction indicated by the arrow H, which can restrict the displacement of the key-top 51 in the direction indicated by the arrow F. Due to the above operation, the key-top 51 is restored to the original position shown in FIG. 10A.

### 2. Configuration of a Protective Sheet

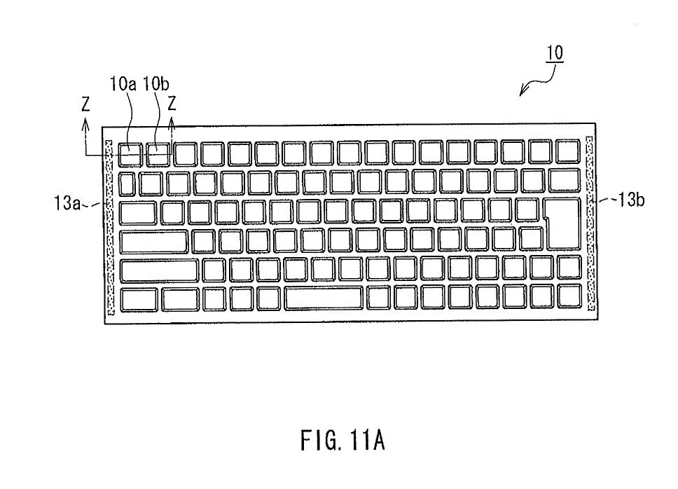

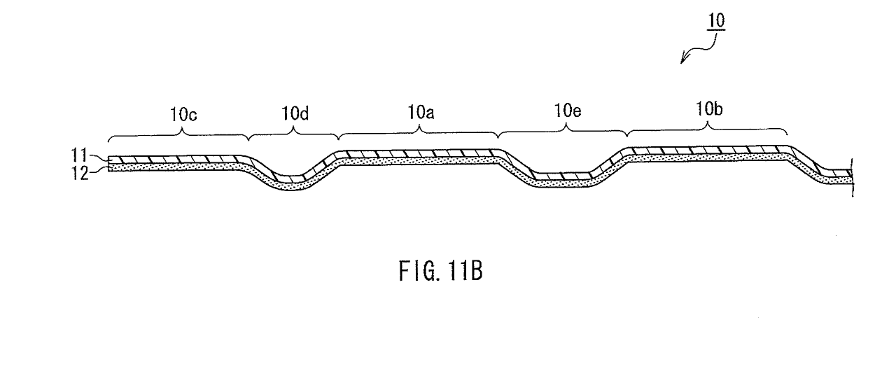

FIG. 11A is a plan view of the protective sheet according to the present embodiment. FIG. 11B is a cross-sectional view taken along a Z-Z portion in FIG. 11A.

A protective sheet 10 is capable of being placed so as to cover the keyboard 5 shown in FIG. 9 or the like. As shown in FIG. 11A, the protective sheet 10 has a first convex portion 10a and a second convex portion 10b at positions corresponding to the respective key-tops mounted on the keyboard 5 (see FIG. 9, etc.). In the present embodiment, although only parts of the convex portions in the protective sheet 10 are denoted with reference numerals as shown in FIG. 11A, the protective sheet 10 is provided with the convex portions at the positions corresponding to all the key-tops provided in the keyboard 5.

As shown in FIG. 11B, the protective sheet 10 has a two-layered structure composed of a first layer 11 and a second layer 12. The first layer 11 is exposed to the surface when the protective sheet 10 is placed on the keyboard 5. More specifically, the first layer 11 is pressed directly with the finger or the like of the user when the protective sheet 10 is placed on the keyboard 5. The first layer 11 can be formed of a skin layer made of, for example, elastically deformable resin. The first layer 11 may be formed of a material having at least elasticity. Further, it is preferred that, for example, a silver-based or phosphorus-based known antibacterial agent is mixed in the first layer 11 if required, since the contamination by users who hit keys can be suppressed when a plurality of users share the keyboard 5. The second layer 12 is in contact with the first layer 11, and comes into contact with the key-tops when the protective sheet 10 is placed on the keyboard 5. The second layer 12 can be formed of, for example, nonwoven fabric. The second layer 12 may be formed of a material having at least a buffering property or sound absorption property, and may be formed of a flexible material such as urethane foam instead of nonwoven fabric.

As shown in FIG. 11B, the protective sheet 10 is formed in an uneven shape corresponding to the height of the key-tops and the gaps between the key-tops of the keyboard 5. The cross-sectional view in FIG. 11B shows a first convex portion 10a, a second convex portion 10b, a third convex portion 10c, a first concave portion 10d, and a second concave portion 10e. The first convex portion 10a corresponds to the key 5a shown in FIG. 9 or 10A. The second convex portion 10b corresponds to a key 5b shown in FIG. 9 or 10A. The third convex portion 10c corresponds to a portion positioned on the periphery of the keyboard 5 in the first housing 1 shown in FIG. 9 or 10A. The first concave portion 10d corresponds to the gap P2 between the key 5a and the first housing 1 shown in FIG. 10A. The second concave portion 10e corresponds to the gap P1 between the key 5a and the key 5b shown in FIG. 10A.

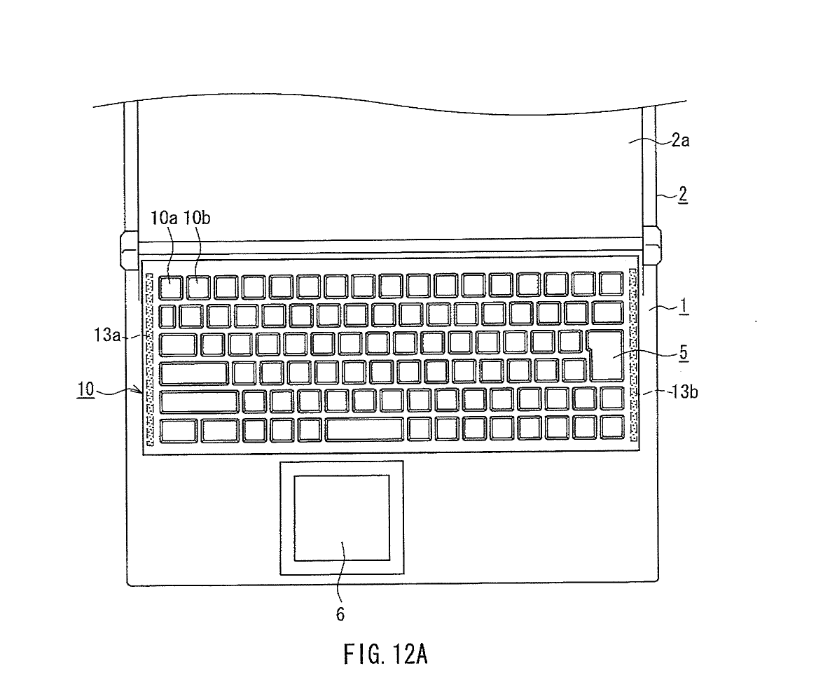

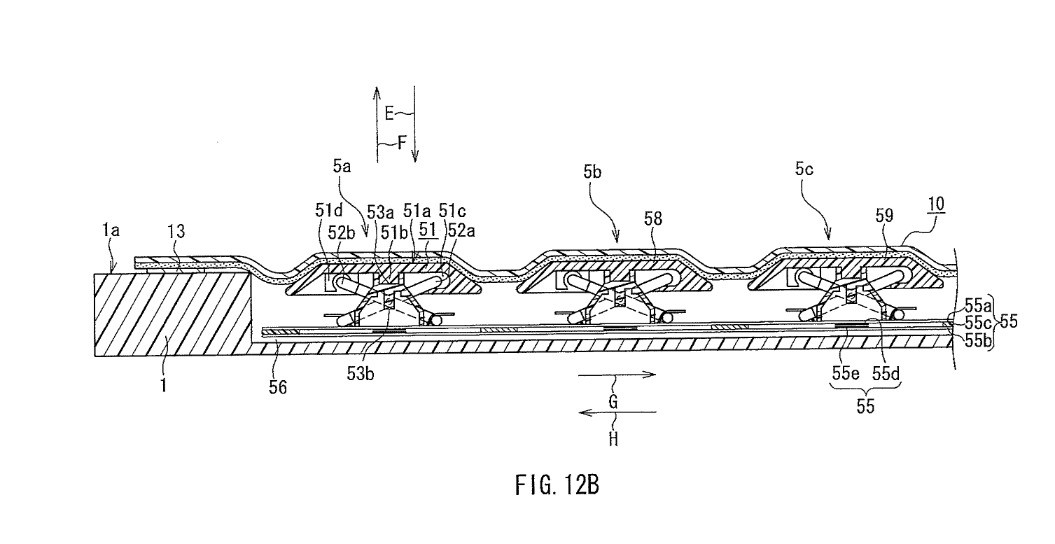

FIG. 12A is a plan view of the keyboard 5 with the protective sheet 10 placed thereon. FIG. 12B is a cross-sectional view taken along a Z-Z portion in FIG. 12A. When the protective sheet 10 is placed on the keyboard 5, the first convex portion 10a of the protective sheet 10 is placed on the key 5a, the second convex portion 10b is placed on the key 5b, the third convex portion 10c is placed on the first housing 1, the first concave portion 10d enters the gap P2 between the key 5a and the first housing 1, and the second concave portion 10e enters the gap P1 between the keys 5a and 5b.

The protective sheet 10 can be fixed to the first housing 1 with a surface fastener 13. The surface fastener 13 is composed of one cloth material with a number of hook-shaped fluffs formed thereon and the other cloth material with a number of loop-shaped fluffs formed thereon, and both the cloth materials can be joined with each other. One cloth material of the surface fastener 13 is attached to the reverse surface (face the second layer 12 side) of the third convex portion 10c of the protective sheet 10 with an adhesive tape or the like. The other cloth material of the surface fastener 13 is attached to the vicinity of the keyboard 5 of the upper surface la of the housing 1 with an adhesive tape or the like. As shown in FIG. 9, the surface fastener 13 is placed along a pair of short sides of the protective sheet 10 (a first surface fastener 13a, a second surface fastener 13b). Thus, after the protective sheet 10 is aligned with the normal position in the keyboard 5, the cloth materials of the surface fastener 13 are joined with each other, whereby the protective sheet 10 can be fixed at the normal position. The “normal portion” refers to the position of the protective sheet 10 when the convex portions of the protective sheet 10 are placed on the key-tops, and the concave portions thereof are placed in the gaps between the key-tops.

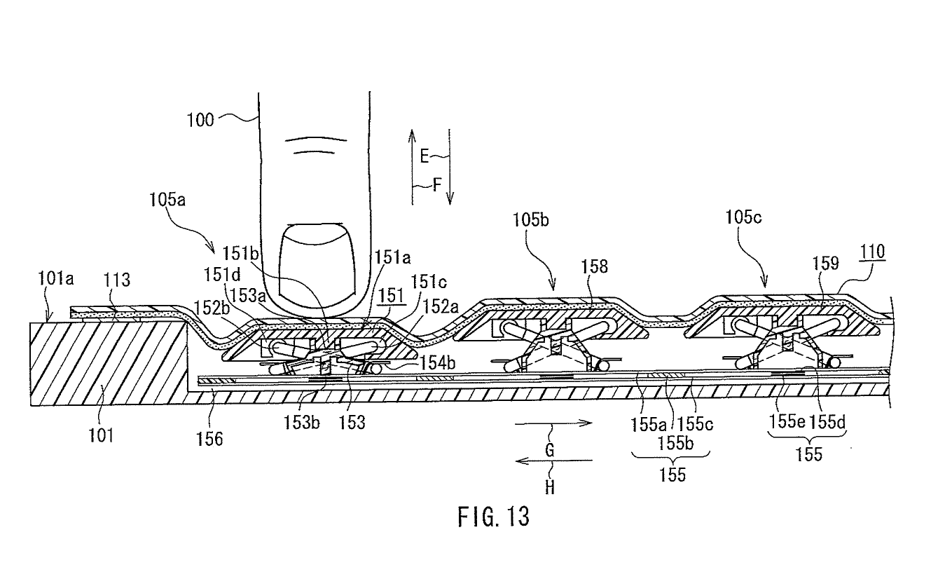

When the user depresses, for example, the key-top 51 of the key 5a in the direction indicated by an arrow E in the state shown in FIG. 12B (state in which the key-top is not depressed), the first convex portion 10a is displaced in the direction indicated by the arrow E together with the key-top 51 while the first concave portion 10d and the second concave portion 10e in the protective sheet 10 mainly are deformed. FIG. 13 is a cross-sectional view showing a state in which the key-top 51 of the key 5a is depressed in the direction indicated by the arrow E. In the state shown in FIG. 13, the first convex portion 10a is sandwiched between a finger 100 of the user and the key-top 51, so that the first convex portion 10a is in contact with the key-top 51. The operation of each movable component when the key-top 51 is depressed is the same as that described above.

In the state (state in which the key-top is depressed) shown in FIG. 13, when the user retracts the finger 100 from the key-top 51 of the key 5a, the key-top 51 rises in the direction indicated by the arrow F due to the resilient restoring force of the dome portion 53. At this time, the first layer 11 of the protective sheet 10 is formed of a material having elasticity, and hence, the protective sheet 10 returns to the original shape under no-load state (state in which the protective sheet 10 is not pressed with the finger or the like) as shown in FIG. 12B.

### 3. Effects of the Embodiment, Etc.

According to the present embodiment, the protective sheet 10 has a two-layered structure including the first layer 11 made of, for example, a skin layer and the second layer 12 made of, for example, nonwoven fabric, whereby the durability of the protective sheet 10 during the use for a long period of time and the durability thereof with respect to the keying of the keyboard can be enhanced, compared with a protective sheet having a single-layered structure. Thus, even when the keyboard 5 with the protective sheet 10 placed thereon is pressed repeatedly, the fatigue of the protective sheet 10 is less and the damage thereof caused by breakage can be reduced, which can prevent liquid and fine particles from entering the reverse side of the key-tops.

When water spills on the keyboard without the protective sheet, water enters the reverse side of the key-tops. However, a residue hardly remains on the reverse side of the key-tops due to the evaporation of the water, and hence, the smoothness of the strokes of the key-tops is impaired less. However, when coffee or juice spills on the keyboard 5 without the protective sheet 10, even if the coffee and juice having entered the reverse side of the key-tops is dried, sugar and the like having viscosity may remain. When such a residue having viscosity adheres to the movable components such as the link members 52a and 52b, the movement of the movable members becomes worse, which may degrade the operability of the keyboard 5. Since the protective sheet 10 of the present embodiment can prevent liquid from entering the reverse side of the key-tops 5, the above problems can be prevented from arising.

Further, in the present embodiment, the gaps P1 and P2 between the key-tops can be covered with the protective sheet 10, so that liquid, fine particles, and the like can be prevented from entering the reverse side of the key-tops. This can prevent liquid, fine particles, and the like from entering the reverse side of the key-tops to impair the operation smoothness of the movable components such as the link members 52a and 52b. Further, it is hardly necessary to remove the key-tops and clean the inside of the keyboard 5.

Further, in the present embodiment, since the gaps P1 and P2 between the key-tops can be covered with the protective sheet 10, the key-tops can be prevented from coming off while the user is operating the keyboard 5. More specifically, in the case of a keyboard without the protective sheet 10 of the present embodiment, when the user is operating the keyboard, the finger tip of the user may enter the gap P1, P2, or the like to lift up the key-top, thereby causing the key-top or mechanical components accompanying the key-top to come off from the keyboard. In the present embodiment, the finger tip of the user can be prevented from entering the gap P1, P2, or the like by covering the gaps P1, P2, etc. between the key-tops with the protective sheet 10. Thus, the finger tip of the user can be prevented from causing the key-top or mechanical components accompanying the key-top to come off from the keyboard.

Further, the protective sheet 10 is configured so as to be detachable or attachable with respect to the keyboard 5 as in the present embodiment, whereby a protective sheet dedicated to each user using a notebook personal computer can be prepared. For example, in the case where a plurality of users share one notebook personal computer, each of the plurality of users can operate the keyboard after attaching a protective sheet dedicated to each user to the keyboard if each user owns the protective sheet dedicated to each user. The user removes the protective sheet dedicated to the user from the keyboard after using the notebook personal computer, and thus, other people will not touch the protective sheet, which is hygienic.

Further, in the present embodiment, the second layer 12 is made of a material having a buffering property such as nonwoven fabric, which can reduce the transmission of an impact caused by the depression of the key-top by the user's finger to the finger. For example, in FIG. 12B, the user depresses the key-top 51 with the finger in the direction indicated by the arrow E, and the key-top 51 is displaced in the direction indicated by the arrow E as shown in FIG. 13, the link members 52a and 52b come into contact with the upper membrane sheet 55a. The impact and vibration that are generated when the link members 52a and 52b come into contact with the upper membrane sheet 55a are transmitted to the key-top 51 through the link members 52a and 52b. In the present embodiment, the second layer 12 formed of nonwoven fabric absorbs the impact and vibration, whereby the impact transmitted to the user's finger from the key-top is reduced. Further, the second layer 12 formed of nonwoven fabric can absorb a keying sound generated when the user depressed the key-top with the finger, and hence, the keying sound can be reduced.

Further, the protective sheet 10 of the present embodiment has a convex portion (first convex portion 10a, etc.) at a position corresponding to the key-top of the keyboard 5 and a concave portion (first concave portion 10d, etc.) at a position corresponding a region between the key-tops, whereby the gap between the protective sheet 10 and the key-tops can be minimized compared with that in the case of using the protective sheet without unevenness, when the protective sheet 10 is placed on the keyboard 5. Thus, the entering of liquid, fine particles, and the like through the gap between the protective sheet 10 and the key-tops can be reduced. For example, in the case where the protective sheet has no unevenness, the gap between the protective sheet and the key-tops is large in a gap portion between the key-tops, which increase the possibility that liquid, fine particles, and the like enter the keyboard through the gap.

Further, the protective sheet 10 of the present embodiment has a convex portion (first convex portion 10a, etc.) at a position corresponding to the key-top of the keyboard 5 and a concave portion (first concave portion 10d, etc.) at a position corresponding a region between the key-tops, whereby the positional shift between the protective sheet 10 and the key-tops can be reduced compared with the case of using the protective sheet without unevenness, when the protective sheet 10 is placed on the keyboard 5. More specifically, since the concave portion of the protective sheet 10 is embedded in the gap between the key-tops, the protective sheet 10 is regulated in terms of the position in a plane direction of the operation surface of the key-tops. Thus, during keying or the like by the user, the positional shift of the protective sheet 10 in the plane direction of the operation surface of the key-tops can be reduced.

Further, the protective sheet 10 of the present embodiment can be fixed to the keyboard 5 with the surface fastener 13, whereby the positional shift of the protective sheet 10 with respect to the keyboard 5 is unlikely to occur while the user is inputting characters using the keyboard 5 with the protective sheet 10 placed thereon. Therefore, the operability is not degraded. Further, in the case where the configuration in which the protective sheet 10 is fixed to the keyboard 5 with the surface fastener 13 is applied to a mobile appliance such as a notebook personal computer, the protective sheet 10 is unlikely to come off from the mobile appliance, so that the mobile appliance can be conveyed while the protective sheet 10 is placed on the keyboard 5.

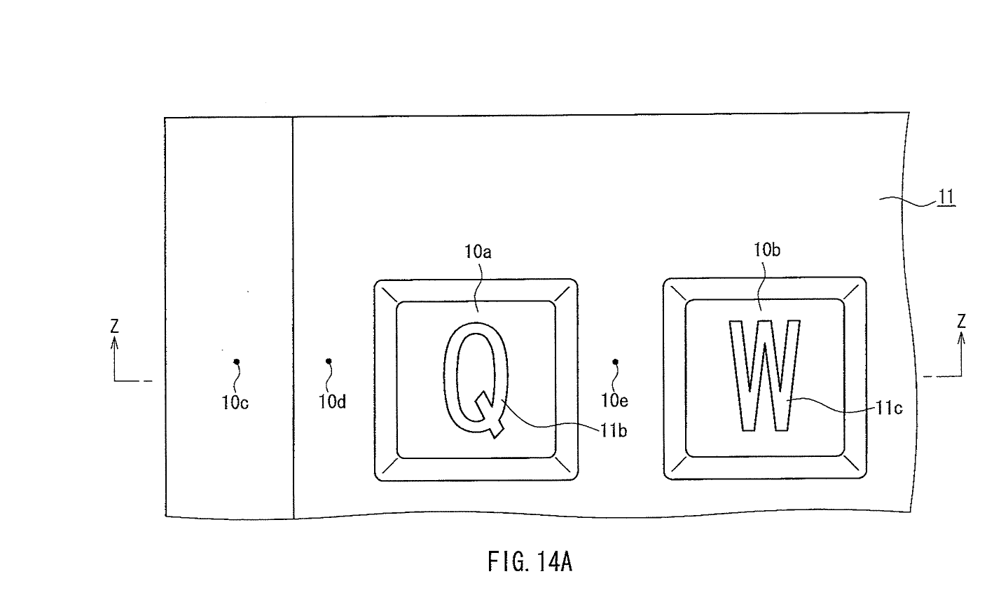

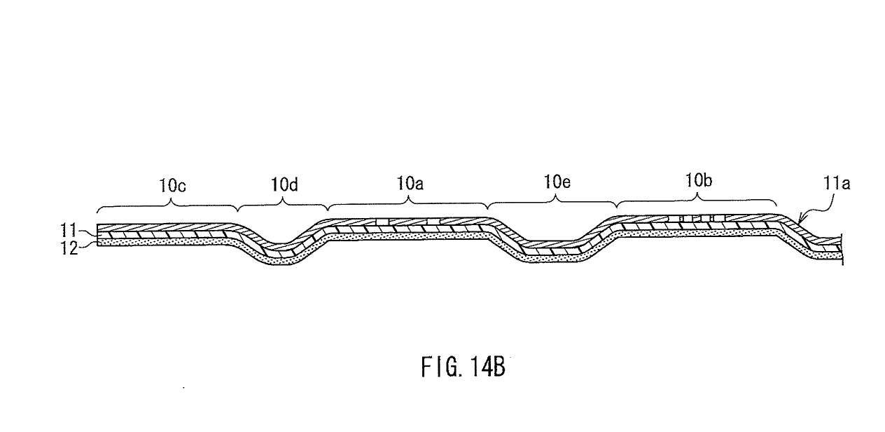

In the present embodiment, although the protective sheet 10 has a two-layered structure including the first layer 11 and the second layer 12, the protective sheet 10 may have a structure of three or more layers. FIGS. 14A and 14B show a protective sheet with a three-layered structure. FIG. 14A is a plan view showing main portions of the protective sheet. FIG. 14B is a cross-sectional view taken along a Z-Z portion in FIG. 14A. As shown in FIG. 14B, the protective sheet has a three-layered structure including the first layer 11, the second layer 12, and the third layer 14. The first layer 11 can be formed of a skin layer of, for example, elastically deformable resin. The first layer 11 has at least a surface 11a (surface which the finger comes into contact with when the user operates the keyboard 5) coated in a dark color such as black. The second layer 12 can be formed of, for example, nonwoven fabric. The third layer 14 can be formed of a skin layer of, for example, elastically deformable resin. The third layer 14 has at least a surface 14a coated in a pale color such as white. As shown in FIGS. 14A and 14B, in the first layer 11, predetermined character cut-away portions 11b and 11c are formed on first convex portions 10a and 10b. The cut-away portion 11b formed on the first convex portion 10a has a shape of a character “Q” as shown in FIG. 14A. The cut-away portion 11c formed on the second convex portion 10b has a shape of “W” as shown in FIG. 14A. Although not shown, other convex portions (convex portions corresponding to the key-tops) in the protective sheet also have cut-away portions having predetermined character shapes. Thus, as shown in FIG. 14A, a white character appears on the surface 11a of the black first layer 11 when the protective sheet is seen from the surface 11a side. Such a configuration makes it unnecessary to print predetermined characters on the surface of the protective sheet. In the case of the protective sheet with predetermined characters printed on the surface, while the user uses the protective sheet for a long period of time, the printed characters may disappear due to the friction between the protective sheet and the fingers. If the first layer 11 is cut away in a character shape to allow the character to appear with the color of the third layer 14 that is an underlying layer of the first layer 11, as shown in FIGS. 14A and 14B, the character will not disappear due to the friction between the finger of the user and the protective sheet.

Further, by providing a character-shaped cut-away portion on the first layer 11 as described above, the present invention also can be applied to a self-emitting keyboard. The self-emitting keyboard has a configuration in which light sources such as LEDs are placed on the reverse side of the key-tops, and the key-tops are formed of a transparent material, whereby the key-tops are allowed to emit light. This enables the keyboard to be seen in a dark place, which can enhance the operability. When a protective sheet without transparency is placed on the self-emitting keyboard, the protective sheet blocks light from the keyboard side, so that it becomes difficult to see the keyboard in a dark place, which degrades the operability. A character-shaped cut-away portion is provided on the first layer 11 to expose a part of the second layer 12 or the third layer 14 that is an underlying layer of the first layer 11 and the second layer 12 or the third layer 14 is formed of a transparent material as in the present embodiment, whereby light from the key-tops can be guided to the surface 11a side of the first layer 11 through the second layer 12 or the third layer 14 and the cut-away portion of the first layer 11. Thus, when the protective sheet is seen from the surface 11a side of the first layer 11, only the characters seem to be emitting light, and the keyboard can be seen and operated in a dark place.

The configuration in which a cut-away portion is provided on the first layer 11 as shown in FIGS. 14A and 14B also can be applied to the protective sheet in a two-layered structure in the present embodiment. More specifically, in the protective sheet in a two-layered structure in which the first layer 11 and the second layer 12 are stacked, the first layer 11 may be provided with a cut-away portion having a character shape corresponding to each key. This can expose a part of the second layer 12 in a character shape through the cut-away portion, so that it is not necessary to print characters on the protective sheet. This configuration is preferred for the following reason: the printed characters may disappear due to the friction between the user's fingers and the protective sheet; however, the characters formed by cut-away portions may not disappear due to the friction between the user's fingers and the protective sheet.

Further, in the configuration in which the first layer 11 is provided with a cut-away portion as shown in FIGS. 14A and 14B, although the color of the underlying layer (second layer 12 or third layer 14) of the first layer 11 is a single color, the underlying layer may have a plurality of colors. For example, in the third layer 14, regions corresponding to keys capable of inputting alphabets are coated in white, the regions corresponding to keys capable of inputting numbers are coated in blue, the regions corresponding to function keys are coated in green, and the regions corresponding to the remaining keys are coated in red. Consequently, in the cut-away portions of the first layer 11, characters having varied colors depending upon the respective regions appear.

Further, although the plane fastener 13 is used as means for fixing the protective sheet 10 to the keyboard 5 in the present embodiment, other fixing means may be used. Examples of the method include: a method for engaging the keyboard 5 with the protective sheet 10 using buttons capable of being engaged with each other; a method for engaging a hook portion with a dented portion, with the hook portion being provided in the protective sheet 10 and the dented portion being provided in the keyboard 5, and a method for allowing magnets to attract each other (or allowing a magnet and metal to attract each other), with magnets having different polarities being provided at the protective sheet 10 and the keyboard 5 (or a magnet being provided at one of the protective sheet 10 and the keyboard 5 and metal being provided at the other).

Further, the first layer 11 in the present embodiment is an example of a first layer of the present invention. The second layer 12 in the present embodiment is an example of a second layer of the present invention. The first convex portion 10a and the second convex portion 10b in the present embodiment are one example of a key-top fitting portion of the present invention. The first concave portion 10d and the second concave portion 10e in the present embodiment are one example of a gap sealing portion of the present invention. The plane fastener 13 in the present embodiment is one example of engagement means of the present invention. The cut-away portions 11b, 11c in the present embodiment are one example of a cut-away portion of the present invention.

### Embodiment 6

### 1. Configuration of an Input Device

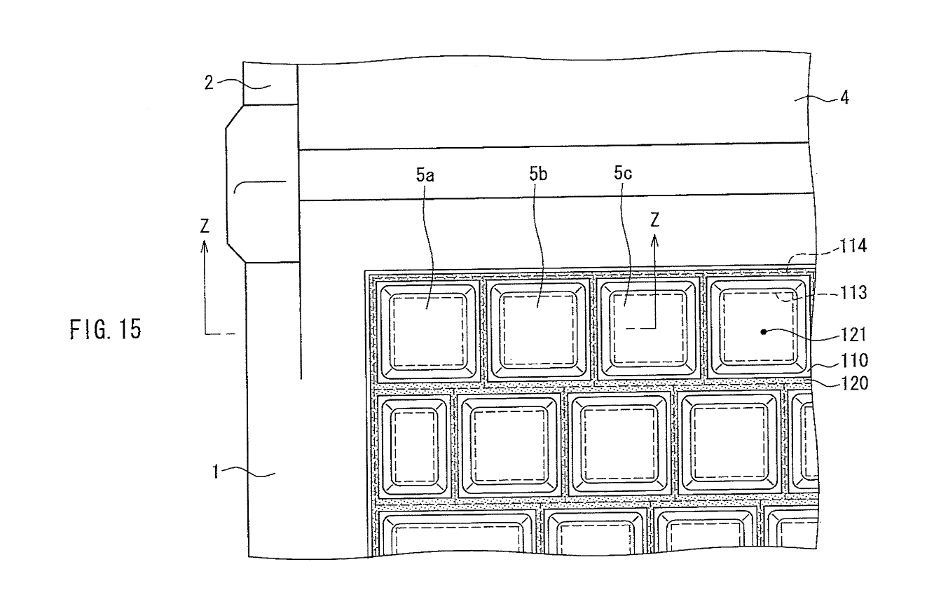

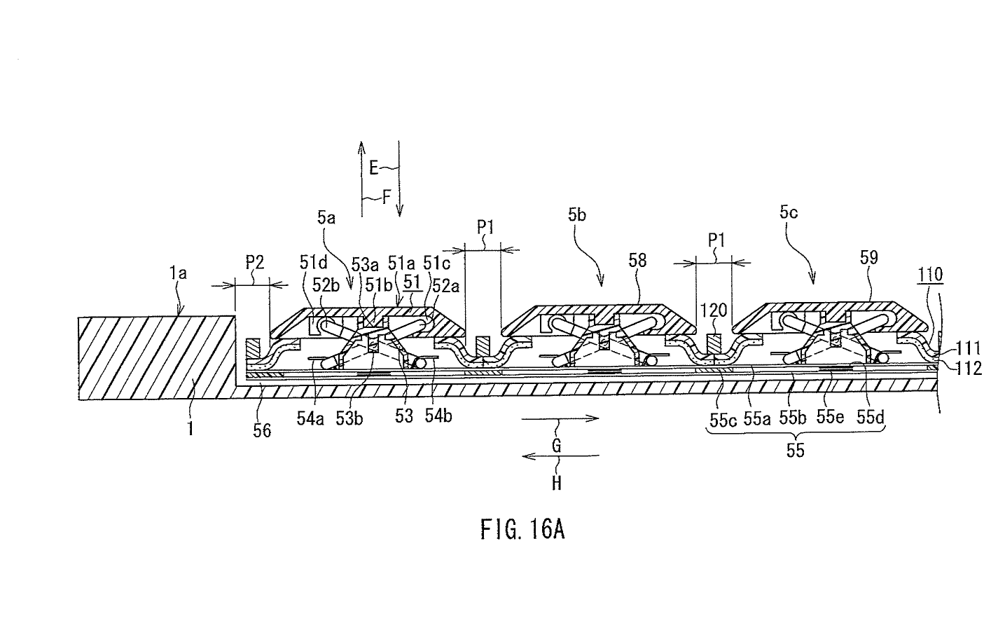

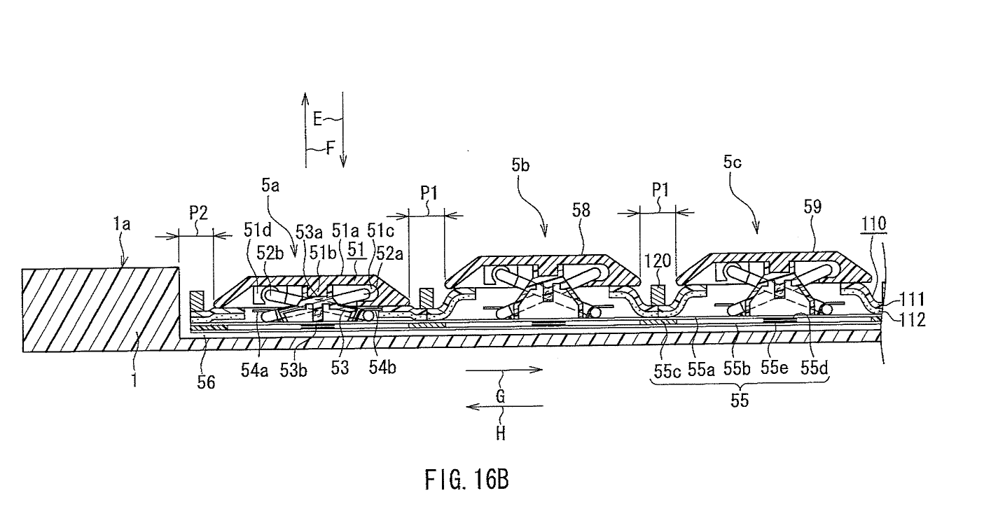

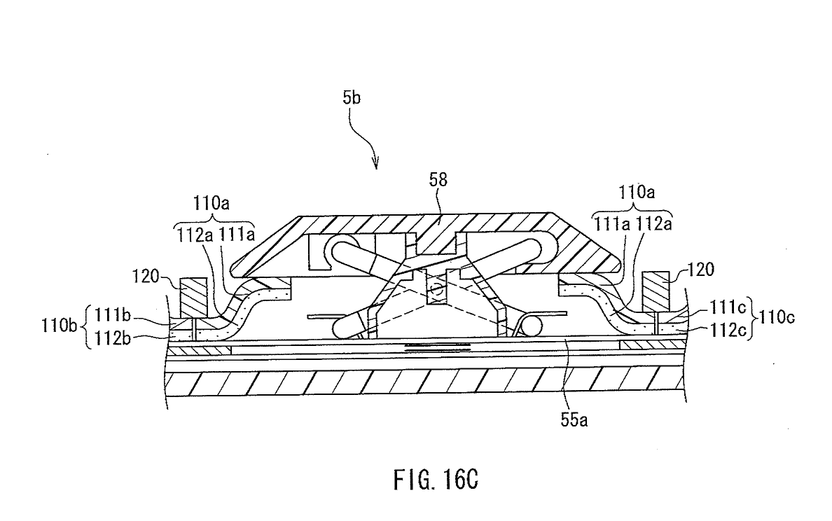

FIG. 15 is a plan view of the keys 5a to 5c in FIG. 9 and the vicinity thereof. FIGS. 16A and 16B are cross-sectional views taken along a Z-Z portion in FIG. 15. FIG. 16A shows a state in which a key is not depressed. FIG. 16B shows a state in which one of the keys is depressed. FIG. 16C is a cross-sectional view of the key 5b in an enlarged state.

### 1-1. Example 1

As shown in FIGS. 15, 16A, and 16B, the keyboard 5 in the present embodiment includes a protective sheet 110 and a frame 120.

The protective sheet 110 is placed independently for each key provided in the keyboard 5. The protective sheet 110 has a two-layered structure having a first layer 111 and a second layer 112 as shown in FIG. 15. The first layer 111 can be formed of a skin layer of, for example, resin that is elastically deformed by contraction or expansion. The first layer 111 may be formed of a material having at least elasticity. The second layer 112 is in contact with the first layer 111. The second layer 112 can be formed of, for example, nonwoven fabric. The second layer 112 may be formed of a material having at least a buffering property or sound absorption property, and may be formed of a flexible material such as urethane foam, instead of nonwoven fabric.

The protective sheet 110 is formed in a shape similar to the plane shape of each key as shown in FIG. 15. As shown in FIG. 15, a hole 113 is formed substantially at the center of a principal plane of the protective sheet 110. The hole 113 allows the link members 52a and 52b and the dome portion 53 to be inserted therethrough as shown in FIG. 16A. A portion in the vicinity of the hole 113 of the protective sheet 110 is fixed to the reverse surface of the key-top 51 of each key with an adhesive or the like. In the protective sheet 110, the portion in the vicinity of an outer circumferential portion 114 is sandwiched between the frame 120 and the upper membrane sheet 55a. In the present embodiment, being “sandwiched” includes the state where the protective sheet is compressed and deformed.

The frame 120 is a member for fixing the protective sheet 110. Although not shown, the frame 120 is supported by the first housing 1 with engagement means such as hook engagement. The frame 120 has a plurality of holes 121 corresponding to the position and size of each key in the keyboard 5, so that the frame 120 is placed so as to surround each key independently. In the hole 121, each key and components accompanying the key are inserted. It is preferred that the frame 120 is formed of, for example, a resin material that is unlikely to be deformed elastically. The frame 120 sandwiches the protective sheet 110 together with the upper membrane sheet 55a. As shown in FIG. 16A, the frame 120 sandwiches the protective sheet 110 placed respectively on adjacent keys in a portion where a plurality of keys are adjacent to each other. It is preferred that the frame 120 sandwiches the protective sheet 110 with a pressure force to such a degree that the protective sheet 110 is compressed and deformed by sandwiching. This ensures that the frame 120 sandwiches the protective sheet 110 exactly, so that a gap is unlikely to be formed between the protective sheet and the flame 120, which can enhance a waterproof property and a dustproof property.

When the user depresses, for example, the key-top 51 from the state shown in FIG. 16A, the key-top 51 is displaced in the direction indicated by the arrow E. At this time, the protective sheet 110 is deformed in the direction indicated by the arrow E along with the displacement of the key-top 51 as shown in FIG. 16B, since the portion in the vicinity of the hole 113 is fixed to the key-top 51. The protective sheet 110 is formed of a material capable of being deformed elastically. Therefore, when the key-top 51 is displaced in the direction indicated by the arrow E from the position shown in FIG. 16A, the protective sheet 110 is compressed and deformed, which is unlikely to prevent the displacement of the key-top 51.

Further, in the state shown in FIG. 16B, when the user retracts the finger from the key-top 51, the key-top 51 rises in the direction indicated by the arrow F due to a resilient restoring force of the dome portion 53. At this time, since the first layer 111 is formed of a material having elasticity, the protective sheet 110 returns to the original shape when it is placed in a non-load state (state in which the protective sheet is not pressed with the finger or the like) as shown in FIG. 16A.

In the keyboard 5 shown in FIGS. 16A and 16B, the sandwiched state of the protective sheet 110 is cancelled when the frame 120 is removed. Thus, the key-top 51 can be removed. The key-top 51 can be washed and the movable components such as the link members 52a and 52b, and the periphery thereof can be cleaned, by removing the key-top 51. When the keyboard 5 is returned to the original state, first, the key-top 51 is placed at a predetermined position. Then, the portion in the vicinity of the outer circumferential portion 112 of the protective sheet 110 is sandwiched together with the upper membrane sheet 55a, and the frame 120 is fixed to a predetermined position in the keyboard 5.

Further, as shown in FIG. 16C, the protective sheet 110a including the first layer 111a and the second layer 112a is fixed to the reverse surface of the key-top 58. The protective sheet 110a fixed to the key-top 58 is separated with respect to the protective sheets 110b and 110c fixed to the key-tops adjacent to the key-top 58. The frame 120 sandwiches the protective sheet 110a, the protective sheet 110b including the first layer 111b and the second layer 112b and the protective sheet 110c including the first layer 111c and the second layer 112c between the frame 120 and the upper membrane sheet 55a. Thus, the key-top 58 and the protective sheet 110a fixed thereto can be removed simultaneously by removing the frame 120. The protective sheet 110a fixed to the key-top 58 is separated with respect to the protective sheets 110b and 110c fixed to the adjacent key-tops. Therefore, each key-top can be removed together with the protective sheet. With such a configuration, only an arbitrary key among a plurality of keys can be washed or cleaned, or for example, when inconvenience is caused in the fitting relationship between the link member 52b and the key 51d of the particular key-top 51 by repeated depression, the defective key-top 58 can be removed together with the protective sheet 110, and a new key-top 58 having the protective sheet 110 is attached instead, whereby only the particular key can be exchanged easily.

### 1-2. Example 2

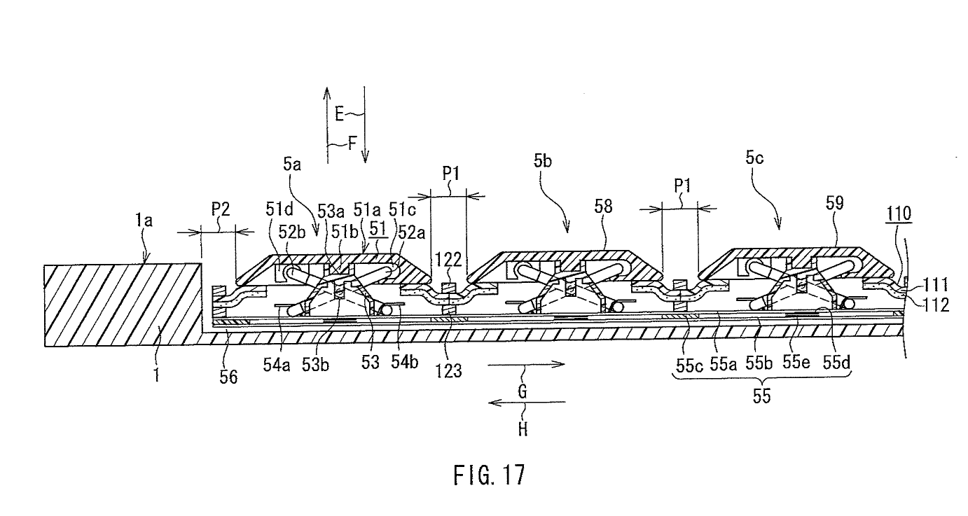

FIG. 17 shows modified examples of the protective sheet and the frame in the present embodiment. In FIG. 17, the same components as those shown in FIGS. 16A and 16B are denoted with the same reference numerals as those therein, and the detailed descriptions thereof will be omitted. What is different between Example 1 and Example 2 lies in the support structure of the protective sheet 110 in the frame 120. Although the protective sheet 110 is sandwiched between the frame 120 and the upper membrane sheet 55a in Example 1, the protective sheet 110 is sandwiched between an upper frame 122 and a lower frame 123 in Example 2.

The frame 120 includes the upper frame 122 and the lower frame 123. The lower frame 123 is fixed to the upper membrane sheet 55a. The upper frame 122 is placed in an upper portion of the lower frame 123, and although not shown, is supported on the first housing 1 by engagement means such as hook engagement. There is a gap capable of sandwiching at least the protective sheet 110 between the upper frame 122 and the lower frame 123. The upper frame 122 and the lower frame 123 are placed so as to surround each key in the keyboard 5 in the same way as in the above-mentioned frame 120. As shown in FIG. 17, the protective sheet 110 placed respectively on adjacent keys is sandwiched by the frame 120 in portions where a plurality of keys are adjacent. It is preferred that the protective sheet 110 is sandwiched by the frame 120 with a pressure force sufficient to compress and deform the protective sheet 110 by sandwiching when the protective sheet 110 is sandwiched.

Thus, the protective sheet 110 can be sandwiched exactly by the frame 120, and hence, a gap is unlikely to be formed between the protective sheet 110 and the frame 120, which can enhance a waterproof property and a dustproof property.

Further, the protective sheet 110 shown in FIG. 17 is fixed to the reverse surface of each key-top and separated on a key-top basis in the same way as in the configuration shown in FIG. 16C. Thus, at least one of the key-tops 51, 58, 59 and the protective sheet 110 fixed thereto can be removed simultaneously by removing the frame 122. With such a configuration, only an arbitrary key among a plurality of keys can be washed or cleaned, or for example, when inconvenience is caused in a fitting relationship between the link member 52b and the key 51d of the particular key-top 51 due to the repeated depression, the key-top 51 can be removed together with the protective sheet 110, so that only the particular key can be exchanged easily.

### 1-3. Example 3

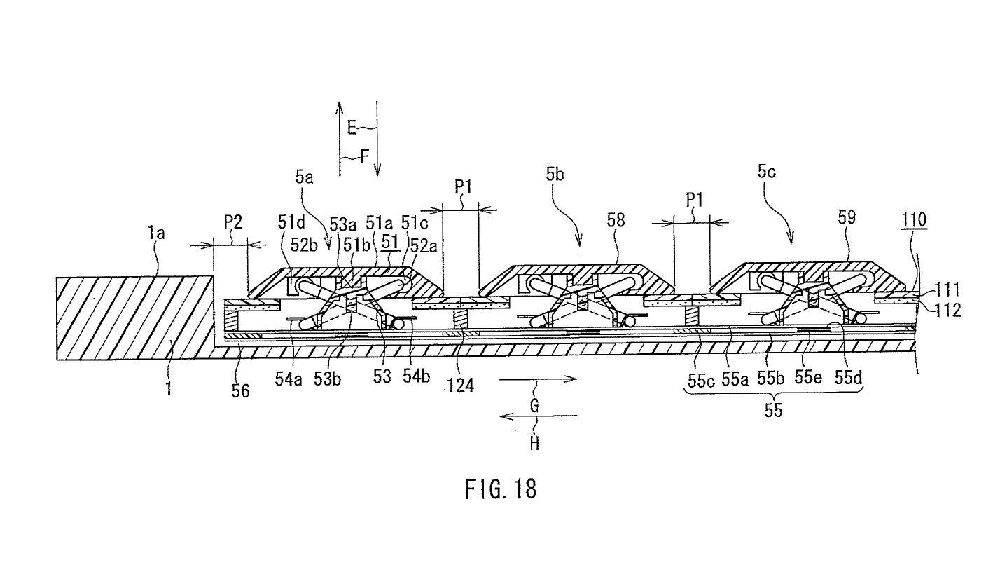

FIG. 18 shows modified examples of the protective sheet and the frame in the present embodiment. In FIG. 18, the same components as those shown in FIGS. 16A and 16B are denoted with the same reference numerals as those therein, and the detailed description thereof will be omitted. What is different between Example 1 and Example 3 lies in the support structure of the protective sheet in the frame. Although the protective sheet 110 is sandwiched between the frame 120 and the upper membrane sheet 55a in Example 1, the protective sheet 110 is supported on an upper portion of the frame 124 in Example 3.

The frame 124 is fixed to the upper membrane sheet 55a. The frame 124 is placed so as to surround each key in the keyboard 5 in the same way as in the frame 120. As shown in FIG. 18, the frame 124 supports the protective sheet 110 placed respectively on adjacent keys in portions where a plurality of keys are adjacent to each other. As a method for supporting the protective sheet 110 with respect to the frame 124, a method for supporting the protective sheet 110 detachably or attachably with a plane fastener or the like is adopted preferably. The protective sheet 110 is configured so as to be detachable or attachable with respect to the frame 124, whereby the key-top 51 can be removed easily from the keyboard 5, and washing of the key-top 51 and cleaning of the movable components and the vicinity thereof can be performed easily.

Further, the protective sheet 110 is fixed to the reverse surface of each key-top and separated on a key-top basis in the same way as in the configuration shown in FIG. 16C. Thus, an arbitrary key-top is removed, and the protective sheet fixed thereto also is removed. With such a configuration, only an arbitrary key among a plurality of keys can be washed or cleaned, or for example, when inconvenience is caused in a fitting relationship between the link member 52b and the key 51d of the particular key-top 51 due to the repeated depression, the key-top 51 can be removed together with the protective sheet 110, so that only the particular key can be exchanged easily.

### 1-4. Example 4

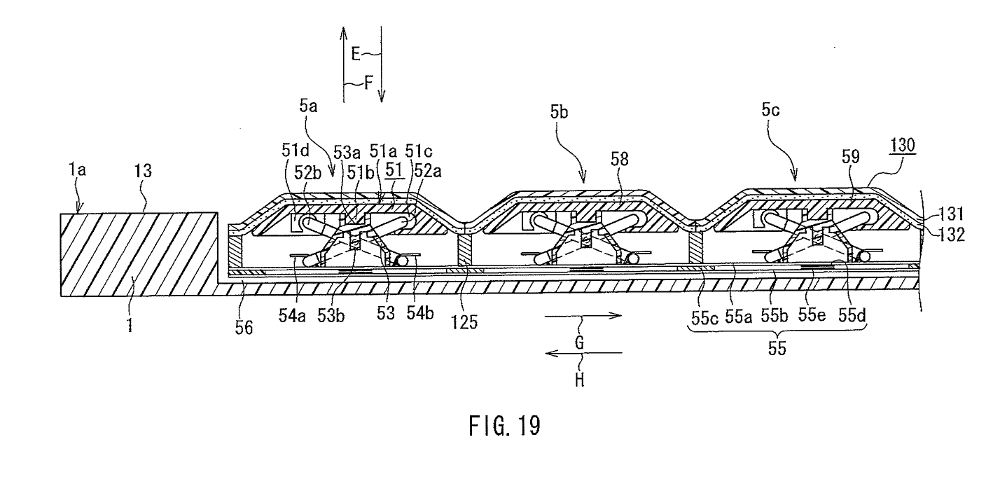

FIG. 19 shows modified examples of the protective sheet and the frame in the present embodiment.

A protective sheet 130 can be placed so as to cover the key-top 51 of each key included in the keyboard 5. The protective sheet 130 is attached along the shape of the operation surface of each key-top of the keyboard 5. More specifically, when a second layer 132 of the protective sheet 130 is allowed to sink, for example, along the shape of the operation surface of each key-top of the keyboard 5, the protective sheet 130 and the keyboard 5 can be positioned easily. It is preferred to adopt a configuration in which the sunk shape of the second layer 132 also is reflected onto the first layer 131, since the keyboard 5 can be attached easily along the protective sheet 130.

The protective sheet 130 has a two-layered structure including a first layer 131 and a second layer 132. The first layer 131 is exposed to the surface when the protective sheet 130 is attached to the keyboard 5. More specifically, the first layer 131 is pressed directly with the finger or the like of the user when the protective sheet 130 is attached to the keyboard 5. The first layer 131 can be formed of a skin layer of, for example, resin that is elastically deformable. The first layer 131 may be formed of a material having at least elasticity. The second layer 132 is in contact with the first layer 131, and comes into contact with the key-top 51 when the protective sheet 130 is placed on the keyboard 5. The second layer 132 can be formed of, for example, nonwoven fabric. The second layer 132 may be formed of a material having at least a buffering property or a sound absorption property, and may be formed of a flexible material such as urethane foam, instead of nonwoven fabric.

The protective sheet 130 can be attached to the operation surface of the key-tops 51 with an adhesive, a plane fastener, or the like. In the case where the protective sheet 130 is fixed to the key-tops 51 with an adhesive, the protective sheet 130 can be fixed to the key-tops 51 exactly. Therefore, there is an advantage in that the protective sheet 130 is not shifted in position from the key-tops 51. When the protective sheet 130 is attached to the key-tops 51 with a plane fastener, the protective sheet 130 can be detached or attached easily with respect to the key-tops 51, and hence, the protective sheet 130 can be exchanged easily or the protective sheet 130 can be removed easily. In this case, for example, even if there is a possibility that a person other than the owner of the keyboard 5 touches the keyboard 5 to contaminate the key-tops and the like, the keyboard 5 can be protected from the contamination by the person by allowing the owner to own the protective sheet 130 personally. The protective sheet 130 has an outer circumferential portion supported by the frame 120, so that the protective sheet 130 only needs to be placed on the key-tops 51 and is not required to be attached thereto.

The frame 125 is fixed to the upper membrane sheet 55a. The frame 125 is placed so as to surround each key in the keyboard 5 in the same way as in the frame 120. As shown in FIG. 19, the frame 125 supports the protective sheet 130 placed respectively on adjacent keys in portions where a plurality of keys are adjacent to each other. As a method for supporting the protective sheet 130 with respect to the frame 125, a method for supporting the protective sheet 130 detachably or attachably with a plane fastener or the like is adopted preferably. The protective sheet 130 is configured so as to be detachable or attachable with respect to the frame 125, whereby the key-tops 51 can be removed from the keyboard 5 easily, and washing of the key-tops 51, cleaning of the movable components and the vicinity thereof, and the like can be performed easily.

Further, the protective sheet 130 is separated on a key-top basis in the same way as in the configuration shown in FIG. 16C. Thus, by removing an arbitrary key-top, the protective sheet 130 fixed thereto also is removed simultaneously. With such a configuration, only an arbitrary key among a plurality of keys can be washed or cleaned, or for example, when inconvenience is caused in a fitting relationship between the link member 52b and the key 51d of the particular key-top 51 due to the repeated depression, the key-top 51 can be removed together with the protective sheet 130, so that only the particular key can be exchanged easily.

### 2. Effects of the Embodiment, Etc.

According to the present embodiment, the protective sheet 110 has a two-layered structure including the first layer 111 made of, for example, a skin layer and the second layer 112 made of, for example, nonwoven fabric, whereby the durability of the protective sheet 110 during the use for a long period of time and the durability thereof with respect to the keying of the keyboard can be enhanced, compared with a protective sheet with a single-layered structure. Thus, even when the keyboard 5 with the protective sheet 110 placed thereon is depressed repeatedly, the fatigue of the protective sheet 110 is less and the damage thereof caused by breakage can be reduced, which can prevent liquid and fine particles from entering the reverse side of the key-tops. The same effects are obtained even in the protective sheet 130.

When water spills on the keyboard without the protective sheet 110, water enters the reverse side of the key-tops. However, a residue hardly remains on the reverse side of the key-tops due to the evaporation of the water, and hence, the smoothness of the strokes of the key-tops is impaired less. However, when coffee or juice spills on the keyboard 5 without the protective sheet 110, even if the coffee and juice having entered the reverse side of the key-tops is dried, sugar and the like having viscosity may remain. When such a residue having viscosity adheres to the movable components such as the link members 52a and 52b, the movement of the movable members becomes worse, which may degrade the operability of the keyboard 5. Since the protective sheet 110 of the present embodiment can prevent liquid from entering the reverse side of the key-tops 5, the above-mentioned problems can be prevented from arising.

Further, in the present embodiment, the gaps P1 and P2 between the key-tops can be covered with the protective sheet 110, so that liquid, fine particles, and the like can be prevented from entering the reverse side of the key-tops. This can prevent liquid, fine particles, and the like from entering the reverse side of the key-tops to impair the operation smoothness of the movable components such as the link members 52a and 52b. Further, it is hardly necessary to remove the key-tops and clean the inside of the keyboard 5. The same effects are obtained even in the protective sheet 130.

Further, in the present embodiment, since the protective sheet 110 positioned between the key-tops is sandwiched by the frame 120, the key-tops can be prevented from coming off while the user is operating the keyboard 5. More specifically, in the case of a keyboard without the protective sheet 110 and the frame 120 of the present embodiment, when the user is operating the keyboard, the finger tip of the user may enter the gap P1, P2, or the like to lift up the key-top, thereby causing the key-top or mechanical components accompanying the key-top to come off from the keyboard. In the present embodiment, the protective sheet 110 and the frame 120 are provided in the gap P1, P2, or the like between the key-tops, which can make it difficult for the finger tip of the user to enter the gap P1, P2, or the like. Thus, the finger tip of the user can be prevented from causing the key-top or mechanical components accompanying the key-top to come off from the keyboard.

Further, in the present embodiment, the second layer 112 is made of a material having a buffering property such as nonwoven fabric, which can reduce the transmission of an impact caused by the depression of the key-top by the user's finger to the finger. For example, in FIG. 16B, when the user depresses the key-top 51 with the finger, and the key-top 51 is displaced in the direction indicated by the arrow E as shown in FIG. 16B, the link members 52a and 52b comes into contact with the upper membrane sheet 55a. The impact and vibration that are generated when the link members 52a and 52b come into contact with the upper membrane sheet 55a are transmitted to the key-top 51 through the link members 52a and 52b. In the present embodiment, the second layer 12 formed of nonwoven fabric absorbs the impact and vibration, whereby the impact transmitted to the user's finger from the key-top is reduced. Further, the second layer 112 formed of nonwoven fabric can absorb a keying sound generated when the user depresses the key-top with the finger, and hence, the keying sound can be reduced.

Further, in the present embodiment, the protective sheet is detachable or attachable to the frame or the upper membrane sheet, whereby the key-top 51 can be detached or attached easily. This is convenient for washing the key-top 51 and for cleaning the movable components supporting the key-top 51 and the periphery thereof.

Further, in the present embodiment, the protective sheet is provided independently on a key basis in the keyboard 5, and the protective sheet 110 is detachable or attachable with respect to the frame or the upper membrane sheet 55a, whereby only the key-top 51 in an arbitrary key among a plurality of keys can be detached or attached. Thus, only an arbitrary key among a plurality of keys can be washed or cleaned, or for example, when inconvenience is caused in a fitting relationship between the link member 52b and the key 51d of the particular key-top 51 due to the repeated depression, the key-top 51 can be removed together with the protective sheet 110, so that only the particular key can be exchanged easily.

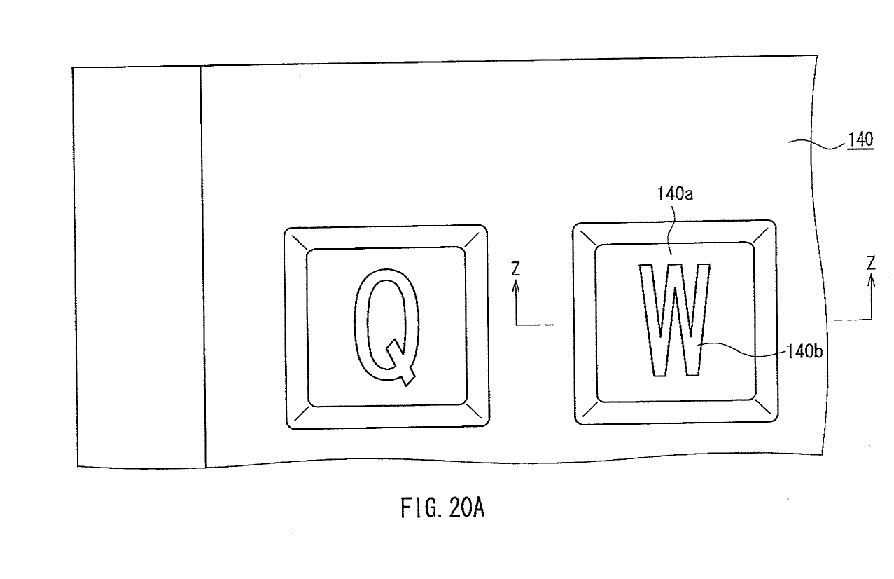

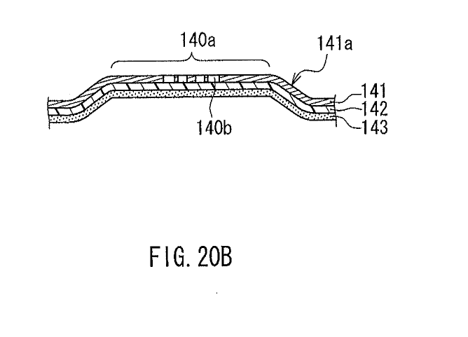

In the present embodiment, although the protective sheet 110 has a two-layered structure including the first layer 111 and the second layer 112, the protective sheet 110 may have a structure of three or more layers. FIGS. 20A and 20B show a protective sheet with a three-layered structure. FIG. 20A is a plan view showing main portions of the protective sheet. FIG. 20B is a cross-sectional view taken along a Z-Z portion in FIG. 20A. As shown in FIG. 20B, the protective sheet 140 has a three-layered structure including a first layer 141, a second layer 142, and a third layer 143. The first layer 141 can be formed of a skin layer of, for example, elastically deformable resin. The second layer 142 can be formed of, for example, nonwoven fabric. The third layer 143 can be formed of a skin layer of, for example, elastically deformable resin. The third layer 143 has at least a surface 141a coated in a pale color such as white. As shown in FIGS. 20A and 20B, in the first layer 141, a predetermined character cut-away portion 140b is formed. The cut-away portion 140b formed on the first convex portion 140a has a shape of a character “W” as shown in FIG. 20A. Although not shown, other convex portions (convex portions corresponding to the key-tops) in the protective sheet also have cut-away portions having predetermined character shapes. Thus, as shown in FIG. 20A, a white character ‘W’ appears on the surface 141a of the black first layer 141 when the protective sheet 140 is seen from the surface 141a side. Such a configuration makes it unnecessary to print predetermined characters on the surface of the protective sheet. While the user uses the protective sheet with predetermined characters printed on the surface for a long period of time, the printed characters may disappear due to the friction between the protective sheet and the fingers. As shown in FIGS. 20A and 20B, if the first layer 141 is cut away in a character shape to allow the character to appear with the color of the second layer 142 that is an underlying layer of the first layer 141, the character will not disappear due to the friction between the finger of the user and the protective sheet.

Further, by providing a character-shaped cut-away portion on the first layer 141 as described above, the present invention can be applied to a self-emitting keyboard. The self-emitting keyboard has a configuration in which light sources such as light-emitting diodes (LEDs) are placed on the reverse side of the key-tops, and the key-tops are formed of a transparent material, whereby the key-tops are allowed to emit light. This enables the keyboard to be seen in a dark place, which can enhance the operability. When a protective sheet without transparency is placed on the self-emitting keyboard, the protective sheet blocks light from the keyboard side, so that it becomes difficult to see the keyboard in a dark place, which degrades the operability. A character-shaped cut-away portion is provided on the first layer 141 to expose a part of the second layer 142 or the third layer 143 that is an underlying layer of the first layer 141 as in the present embodiment, and the second layer 142 or the third layer 143 is formed of a transparent material, whereby light from the key-tops can be guided to the surface 141a side of the first layer 141 through the second layer 142 or the third layer 143 and the cut-away portion of the first layer 11. Thus, when the protective sheet is seen from the surface 141a side of the first layer 141, only the characters seem to emit light, and the keyboard can be seen and operated in a dark place.

The configuration in which a cut-away portion is provided on the first layer 141 as shown in FIGS. 20A and 20B also can be applied to the protective sheet with a two-layered structure in the present embodiment. For example, in the protective sheet with a two-layered structure shown in FIG. 16A, the first layer 111 may be provided with a cut-away portion having a character shape corresponding to each key. This can expose a part of the second layer 112 in a character shape through the cut-away portion, so that it is not necessary to print characters on the protective sheet. This configuration is preferred for the following reason: the printed characters may disappear due to the friction between the user's fingers and the protective sheet; however, the characters formed by cut-away portions may not disappear due to the friction between the user's fingers and the protective sheet.

Further, in the configuration in which the first layer 141 is provided with a cut-away portion as shown in FIGS. 20A and 20B, the color of the underlying layer (second layer 142 or third layer 143) of the first layer 141 may be a single color or a plurality of colors. For example, in the second layer 142, regions corresponding to keys capable of inputting alphabets are coated in white, the regions corresponding to keys capable of inputting numbers are coated in blue, the regions corresponding to function keys are coated in green, and the regions corresponding to the remaining keys are coated in red. Consequently, in the cut-away portions of the first layer 141, characters having varied colors depending upon the respective regions appear.

Further, in the present embodiment, although the protective sheet 110 is fixed to the key-tops 51, the protective sheet 110 can be configured so as to be detached or attached with respective to the key-tops 51. The protective sheet 110 can be supported on the key-tops 51 with, for example, a plane fastener. With such a configuration, when only the key-top 51 is exchanged with a new key-top or when only the protective sheet 110 is exchanged with a new protective sheet, the component can be exchanged easily.

### Embodiment 7

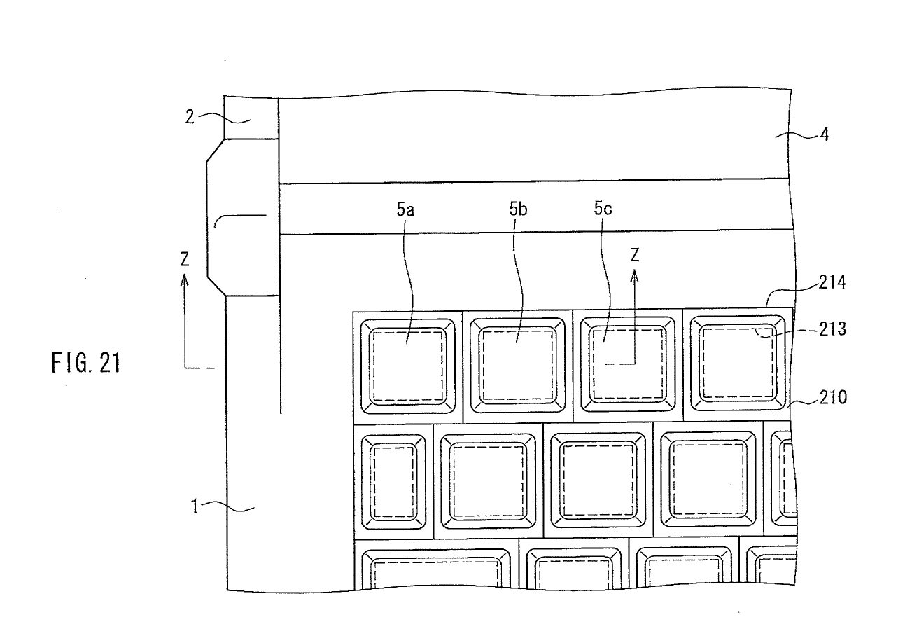

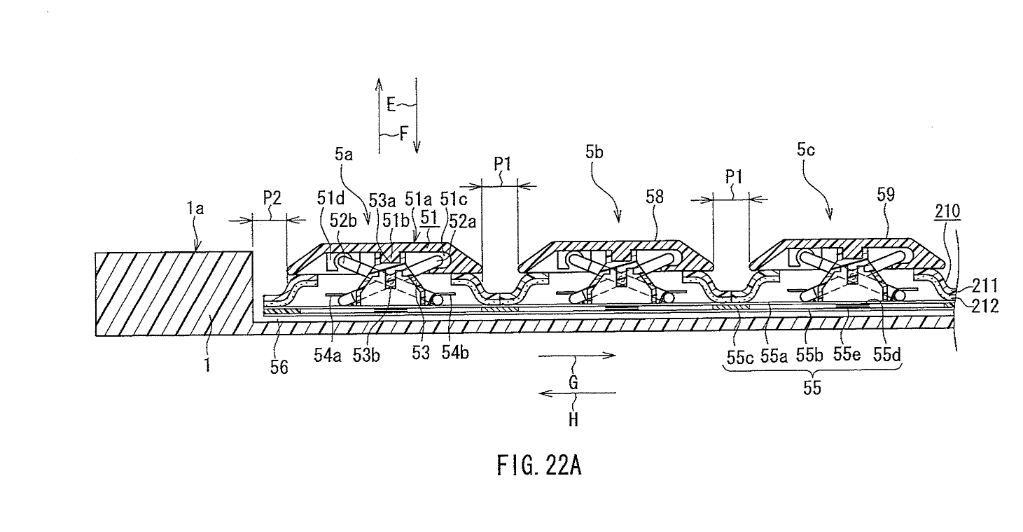

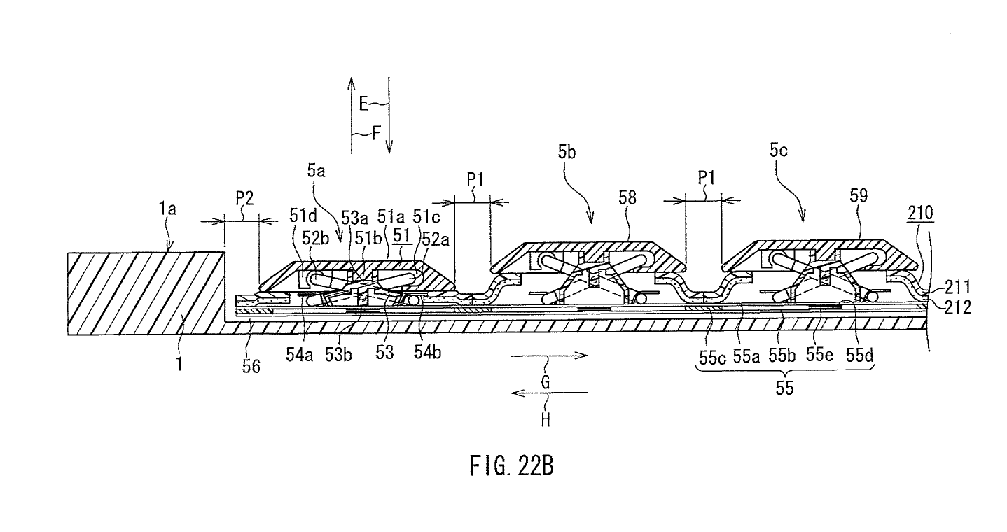

FIG. 21 is a plan view of the keys 5a to 5c in FIG. 9 and the vicinity thereof. FIGS. 22A and 22B are cross-sectional views taken along a Z-Z portion in FIG. 10. FIG. 22A shows a state in which keys are not depressed. FIG. 22B shows a state in which one of the keys is depressed.

As shown in FIGS. 21, 22A, and 22B, the keyboard 5 in the present embodiment includes a protective sheet 210.

The protective sheet 210 is placed independently on a key basis in the keyboard 5. The protective sheet 210 has a two-layered structure including a first layer 211 and a second layer 212 as shown in FIG. 21. The first layer 211 can be formed of a skin layer of, for example, resin that can be elastically deformable by contraction or expansion. The first layer 211 may be formed of a material having at least elasticity. The second layer 212 is in contact with the first layer 211. The second layer 212 can be formed of, for example, nonwoven fabric. The second layer 212 may be formed of a material having at least a buffering property or a sound absorption property, and may be formed of a flexible material such as urethane foam, instead of nonwoven fabric.

The protective sheet 210 is formed in a shape similar to the plane shape of each key as shown in FIG. 21. In the protective sheet 210, a hole 213 is formed substantially at the center of a principal plane of the protective sheet 210, as shown in FIG. 21. The hole 213 allows the link members 52a and 52b and the dome portion 53 to be inserted therethrough as shown in FIG. 22A. A portion in the vicinity of the hole 213 of the protective sheet 210 is fixed to the reverse surface of the key-top 51 of each key with an adhesive or the like. The portion in the vicinity of an outer circumferential portion 214 of the protective sheet 210 is supported by the upper membrane sheet 55a. The outer circumferential portion 214 of the protective sheet 210 and the upper membrane sheet 55a are supported detachably or attachably with a plane fastener or the like. The outer circumferential portion 214 and the upper membrane sheet 55a are supported detachably or attachably, whereby the key-tops 51 can be detached or attached easily. This is convenient for washing the key-tops 51 and cleaning the mobile components supporting the key-top 51 and the periphery thereof.

Furthermore, the protective sheet 210 is placed so as to surround the circumference of each key-top 51 and is connected to the key-tops 51 and the upper membrane sheet 55a. Therefore, water or the like entering from outside can be prevented from adhering to the reverse side of the key-tops 51 or the mobile components that allow the key-top 51 to be keyed in the direction indicated by an arrow E or F. Thus, even if the user drops liquid on the keyboard 5 by mistake, the liquid can be prevented from entering the reverse side of the key-top 51 or the periphery of the mobile components. Further, fine particles such as dust can be prevented from entering the reverse side of the key-top 51 or the periphery of the mobile components.

When the user depresses, for example, the key-top 51 from the state shown in FIG. 22A, the key-top 51 is displaced in the direction indicated by the arrow E. At this time, since a portion in the vicinity of the hole 213 of the protective sheet 210 is fixed to the key-top 51, the protective sheet 210 is deformed in the direction indicated by the arrow E along with the displacement of the key-top 51 as shown in FIG. 22B. Since the protective sheet 210 is formed of a material that can be elastically deformed, the protective sheet 210 is compressed and deformed when the key-top 51 is displaced in the direction indicated by the arrow E from the position shown in FIG. 22A, which makes it difficult to prevent the displacement of the key-top 51.

Further, in the state shown in FIG. 22B, when the user detaches the finger from the key-top 51, the key-top 51 rises in the direction indicated by the arrow F due to a resilient restoring force of the dome portion 53. At this time, since the first layer 211 is formed of a material having elasticity, the protective sheet 210 returns to the original shape under a non-load state (state in which the protective sheet 210 is not depressed with the finger or the like) as shown in FIG. 22A.

According to the present embodiment, the protective sheet 210 has a two-layered structure including the first layer 211 made of, for example, a skin layer and the second layer 212 made of, for example, nonwoven fabric, whereby the durability of the protective sheet 210 during the use for a long period of time and the durability thereof with respect to the keying of the keyboard can be enhanced, compared with a protective sheet with a single-layered structure. Thus, even when the keyboard 5 with the protective sheet 210 placed thereon is pressed repeatedly, the fatigue of the protective sheet 210 is less and the damage thereof caused by breakage can be reduced, which can prevent liquid and fine particles from entering the reverse side of the key-tops. The same effects are obtained even in the protective sheet 130.

When water spills on the keyboard without the protective sheet 210, water enters the reverse side of the key-tops. However, a residue hardly remains on the reverse side of the key-tops due to the evaporation of the water, and hence, the smoothness of the strokes of the key-tops is impaired less. However, when coffee or juice spills on the keyboard 5 without the protective sheet 210, even if the coffee and juice having entered the reverse side of the key-tops is dried, sugar and the like having viscosity may remain. When such a residue having viscosity adheres to the movable components such as the link members 52a and 52b, the movement of the movable components becomes worse, which may degrade the operability of the keyboard 5. Since the protective sheet 210 of the present embodiment can prevent liquid from entering the reverse side of the key-tops 5, the above-mentioned problems can be prevented from arising.

Further, in the present embodiment, the gaps P1 and P2 between the key-tops can be covered with the protective sheet 210, so that liquid, fine particles, and the like can be prevented from entering the reverse side of the key-tops 51. This can prevent liquid, fine particles, and the like from entering the reverse side of the key-tops 51 to impair the operation smoothness of the movable components such as the link members 52a and 52b. Further, it is hardly necessary to remove the key-tops 51 and clean the inside of the keyboard 5.

Further, in the present embodiment, the second layer 212 is made of a material having a buffering property such as nonwoven fabric, which can reduce the transmission of an impact caused by the depression of the key-top by the user's finger to the finger. For example, in FIG. 22A, when the user depresses the key-top 51 with the finger, and the key-top 51 is displaced in the direction indicated by the arrow E as shown in FIG. 22B, the link members 52a and 52b come into contact with the upper membrane sheet 55a. The impact and vibration that are generated when the link members 52a and 52b come into contact with the upper membrane sheet 55a are transmitted to the key-top 51 through the link members 52a and 52b. In the present embodiment, the second layer 212 formed of nonwoven fabric absorbs the impact and vibration, whereby the impact transmitted to the user's finger from the key-top is reduced. Further, the second layer 212 formed of nonwoven fabric can absorb a keying sound generated when the user depresses the key-top with the finger, and hence, the keying sound can be reduced.

Further, in the present embodiment, the protective sheet 210 is detachable or attachable to the upper membrane sheet 55a, whereby the key-top 51 can be detached or attached easily. This is convenient for washing the key-top 51 and for cleaning the movable components supporting the key-top 51 and the periphery thereof.

Further, in the present embodiment, the protective sheet 210 is provided independently on a key basis in the keyboard 5 and is detachable or attachable to the upper membrane sheet 55a, whereby only the key-top 51 of an arbitrary key among a plurality of keys can be detached or attached. Thus, only an arbitrary key among a plurality of keys can be washed or cleaned, or for example, when inconvenience is caused in a fitting relationship between the link member 52b and the key 51d of the particular key-top 51 due to the repeated depression, the key-top 51 can be removed together with the protective sheet 210, so that only the particular key can be exchanged easily.

In the present embodiment, although the protective sheet 210 has a two-layered structure including the first layer 211 and the second layer 212, the protective sheet 210 may have a structure of three or more layers.

Further, in the present embodiment, although the protective sheet 210 is fixed to the key-tops 51, the protective sheet 210 can be configured so as to be detached or attached with respective to the key-tops 51. The protective sheet 210 can be supported by the key-tops 51 with, for example, a plane fastener. With such a configuration, when only the key-top 51 is exchanged with a new key-top or only the protective sheet 110 is exchanged with a new protective sheet, the component can be exchanged easily.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. An input device, comprising:
a plurality of key-tops;
an up-and-down mechanism that supports the key-top so that the key-top rises or falls freely;
a contact portion that is switched in synchronization with a rise-and-fall operation of the key-top; and
a sheet member placed between the key-top and the contact portion,
wherein the sheet member is fixed to a reverse surface of the key-top.

2. The input device according to claim 1, further comprising a support plate placed on the reverse surface of the key-top,
wherein the sheet member is sandwiched and fixed between the key-top and the support plate.

3. The input device according to claim 1, wherein the sheet member has looseness in a portion placed between the key-tops adjacent to each other so that a length of the sheet member in the portion is larger than a distance between the key-tops adjacent to each other.

4. The input device according to claim 3, wherein the looseness of the sheet member is set so that a distance from a portion where the sheet member is fixed to a bent portion is at least ½ of a stroke amount of the rise-and-fall operation of the key-top.

5. An input device including a plurality of input portions, comprising a protective sheet capable of covering at least regions between the input portions,
wherein the protective sheet is formed of a plurality of layers including at least a first layer and a second layer,
the first layer contains a material having elasticity; and
the second layer contains a material having a buffering property.

6. The input device according to claim 5, wherein the protective sheet is independent on a basis of the plurality of input portions.

7. The input device according to claim 5, further comprising a frame that is placed between adjacent input portions among the plurality of input portions and that supports the protective sheet.

8. The input device according to claim 5, wherein the protective sheet is detachable or attachable with respect to the frame.

9. The input device according to claim 5, wherein the input portion includes:
a key-top;
a mobile component that supports the key-top displaceably; and
a membrane switch that supports the mobile component and that is shifted to an ON state or an OFF state by the mobile component along with displacement of the key-top,
wherein the protective sheet is supported by the membrane switch.

10. The input device according to claim 9, wherein the protective sheet is supported by the membrane switch detachably/attachably.

11. A protective sheet capable of covering an input portion of an input device, which is formed of a plurality of layers including at least a first layer and a second layer,
wherein the first layer contains a material having elasticity, and
the second layer contains a material having a buffering property.

12. The protective sheet according to claim 11, wherein the second layer is connected to a principal plane of the first layer.

13. The protective sheet according to claim 11, wherein the input portion includes a key-top, a support member that supports the key-top so that the key-top is capable of moving in a predetermined direction, and a switch placed in a lower portion of the key-top,
wherein a key-top fitting portion is formed so that, when the input portion is covered, the key-top is fitted in the key-top fitting portion from the second layer side.

14. The protective sheet according to claim 13, wherein the input portion includes a plurality of key-tops, and the protective sheet includes a gap sealing portion that seals a gap between adjacent key-tops among the plurality of key-tops when the input portion is covered.

15. The protective sheet according to claim 11, wherein the second layer is formed of nonwoven fabric.

16. The protective sheet according to claim 11, wherein the second layer includes a locking unit capable of locking the second layer with the input device.

17. The protective sheet according to claim 16, wherein the locking unit is a plane fastener.

18. The protective sheet according to claim 11, wherein the first layer is provided with a cut-away portion having a shape of a predetermined character or symbol.

19. The protective sheet according to claim 18, wherein a portion of the second layer that is exposed through at least the cut-away portion is colored in a color different from a color in a vicinity of the cut-away portion in the first layer.

20. The protective sheet according to claim 18, wherein a portion of the second layer that is exposed at least through the cut-away portion has transparency.
